(19) United States
(12) Patent Application Publication
(10) Pub. No.: US 2026/0153801 A1
(43) Pub. Date: Jun. 4, 2026

(54) ORGANOTIN COMPOSITIONS WITH IODO SPECIES AND RADIATION SENSITIVE FILMS

(71) Applicant: Inpria Corporation, Corvallis, OR (US)

(72) Inventors: Robert E. Jilek, Philomath, OR (US); Lauren B. McQuade, Albany, OR (US); Alexander C. Marwitz, Corvallis, OR (US); Munendra Yadav, Corvallis, OR (US); Brian J. Cardineau, Corvallis, OR (US)

(21) Appl. No.: 19/404,631

(22) Filed: Dec. 1, 2025

Related U.S. Application Data
(60) Provisional application No. 63/726,822, filed on Dec. 2, 2024.

(51) Int. Cl. G03F 7/004

(52) U.S. Cl. CPC G03F 7/0045; G03F 7/0042

(57) ABSTRACT

Organometallic patterning compositions are modified with iodine to improve radiation sensitivity and reduce radiation dose without significant loss of pattern quality. Iodine can be introduced as ligands to the metal ion and/or through introduction of iodide containing additives. Iodine is found to survive, at least in part, pre-irradiation processing. Thus, iodide ions are maintained in some form in the films being irradiated.

### CROSS REFERENCE TO RELATED APPLICATIONS

This application claims priority to co-pending provisional U.S. Patent Application 63/726,822 to Marwitz et al. filed Dec. 2, 2025 and titled “Organotin Compositions With Iodo Species and Radiation Sensitive Films”, which is hereby incorporated by reference.

### FIELD OF THE INVENTION

The invention pertains to tin-based organometallic photoresist materials having organic ligands, iodo ligands, or combinations thereof, as well as optionally iodide ions within an oxo-hydoxo network. The invention further relates to precursor solutions for coating the organotin iodo compositions on a substrate and to coatings formed therefrom and to methods for lithographically patterning the coatings. The invention also pertains to tin-based organometallic photoresist coating solutions with iodide additives and to coatings formed therefrom and to associated methods for lithographically patterning the coatings.

### BACKGROUND OF THE INVENTION

Semiconductor lithography is a complex and critical technology used to fabricate myriad and diverse devices that have dominated and transformed the modern world beginning in the 20^{th} century. The semiconductor lithographic process is generally an iterative process involving repeated steps of deposition, patterning, and etching of many layers and materials to form the desired devices. As technology advances and new, increasing demands and requirements are placed upon each generation of devices, the need to develop processes and materials that are able to meet these requirements increases. One of the critical materials used in the semiconductor lithographic process is the photoresist in which an initial pattern is formed by exposure to radiation and is then subsequently transferred into the underlying substrate.

Organometallic photoresists have been shown to be promising materials for use in current and next-generation semiconductor lithography processing due to their ability to form high-resolution, high etch resistance, and high-fidelity patterns. These organometallic systems generally operate through radiation exposure-mediated formation of condensed oxide networks that drive contrast between irradiated (i.e., exposed) and non-irradiated (i.e., unexposed) regions of the material. A development process can then be used that can selectively remove the irradiated or the non-irradiated material to realize a physical pattern of material based on a latent image formed by the pattern of radiation.

### BRIEF DESCRIPTION OF THE DRAWINGS

FIG. 1 is a cartoon depicting proposed mechanisms of chemical change in an iodide enhanced organotin coating and a non-enhanced organotin coating before and after a PEB temperature selected to induce sufficient dealkylation at a low exposure dose.

FIG. 2 is a set of ¹¹⁹Sn NMR spectra for organotin precursor blends formed from varying ratios of organotin trialkoxides and organotin triiodies.

FIG. 3 is a plot of the normalized C—H peak area, as determined by FTIR, as a function of bake temperature for coatings deposited from iodide supplying organotin precursor solutions (TA1, TA2, TA3, TA4) and from a comparative example precursor solution CS-3 comprising no iodide.

FIG. 4 is a plot of the normalized C—H peak area, as determined by FTIR, as a function of bake temperature for coatings deposited from 3 ammonium iodide enhanced precursor solutions (SI1, SI2, SI3) and a non-enhanced comparative example SS.

FIG. 5 is a set of histograms depicting the elemental composition relative to Sn of two coatings deposited from iodide enhanced organotin precursor solutions UA1 and UA2.

FIG. 6 is a set of scanning electron microscopy (SEM) images for coatings deposited from two ammonium iodide enhanced precursor solutions (RA1 and RA2) and a comparative example precursor solution RC comprising no iodide. The coatings were exposed with 22p38 contact hole patterns using EUV radiation, subjected to PEB treatments at three temperatures, and developed to form positive tone patterns.

FIG. 7 is a set of negative tone EUV contrast curves at varying PEB temperatures for coatings deposited from three precursor solutions comprising tertiary/primary organotin compounds without (ZC) or with ammonium iodide (ZA1 and ZA2).

FIG. 8 is a set of negative tone EUV contrast curves at varying PEB temperatures for coatings deposited from two precursor solutions comprising secondary organotin compounds without (YC) or with ammonium iodide (YA1).

### SUMMARY OF THE INVENTION

In a first aspect, the invention pertains to a photoresist precursor solution comprising a mixture of a solvent, an organotin composition represented by the formula RSnL₃ and an ammonium-based iodide compound represented by the formula NR″₄I. R is a organo ligand with one or more carbon atoms optionally substituted with one or more heteroatoms and wherein the organo ligand comprises an alkyl, an aryl, an alkenyl, or a cycloalkyl group with 1-31 carbon atoms with a carbon atom bound to the tin, L is a hydrolysable ligand, and each R″ is independently hydrogen or an organo group with 1 to 10 carbon atoms.

In a further aspect, the invention pertains to a method for preparing a photoresist precursor solution comprising: combining in any order:
a solvent,
an organotin composition represented by the formula RSnL₃ and
an ammonium-based iodide compound represented by the formula NR″₄I.
   R is an organo ligand with one or more carbon atoms optionally substituted with one or more heteroatoms and wherein the organo ligand comprises an alkyl, an aryl, an alkenyl, or a cycloalkyl group with 1-31 carbon atoms, L is a hydrolysable ligand, and each R″ is independently hydrogen or an organo group with 1 to 10 carbon atoms.

In another aspect, the invention pertains to a radiation patternable organometallic coating comprising a tin oxo-hydroxo network with organo ligands bonded to the tin via Sn—C bonds and incorporated iodine, wherein the organo ligands comprise an alkyl, an aryl, an alkenyl, an alkynyl, or a cycloalkyl group with 1-31 carbon atoms wherein one or more carbon atoms are optionally substituted with heteroatoms. An article can comprise a substrate and the radiation patternable coating.

In an additional aspect, the invention pertains to a method for patterning an organometallic coating comprising a tin oxo-hydroxo network with organo ligands bonded to the tin via Sn—C bonds and incorporated iodine atoms, wherein the organo ligands comprise an alkyl, an aryl, an alkenyl, or a cycloalkyl group with 1-31 carbon atoms wherein one or more carbon atoms are optionally substituted with heteroatoms, the method comprising:

exposing a pattern of radiation of the coating to form a latent image comprising exposed and unexposed regions and developing the coating with a developer composition to selectively remove either the exposed material or the unexposed material.

In other aspects, the invention pertains to a composition comprising:
an organotin iodo-alkoxide compound represented by the formula RSn(OR′)₃₋ₓIₓ, and
an organotin alkoxide compound represented by the formula RSn(OR′)₃, wherein R is an organo ligand with one or more carbon atoms. The organo ligand comprises an alkyl, an aryl, an alkenyl, or a cycloalkyl group with 1-31 carbon atoms optionally substituted with one or more heteroatoms, R′ is an organo group with 1 to 10 carbon atoms, and x is 1, 2, 3 or a mixture thereof and has a carbon-tin bond.

Furthermore, the invention pertains to a method of forming a radiation patternable coating, comprising:
depositing a composition comprising a solvent and an organotin iodo-alkoxide composition represented by the formula RSn(OR′)₃₋ₓIₓ onto a substrate, wherein R is an organo ligand with one or more carbon atoms and wherein the organo ligand comprises an alkyl, an aryl, an alkenyl, or a cycloalkyl group with 1-31 carbon atoms optionally substituted with one or more heteroatoms, R′ is an organo group with 1 to 10 carbon atoms, and x is 1, 2, or 3; and
forming a radiation patternable organotin oxo-hydroxo-iodo coating on the substrate.

In some aspects, the invention pertains to a radiation patternable coating comprising: an organotin oxo-hydroxo-iodo network comprising a material represented by the stoichiometry RSnO_{3/2-x/2-z/2}(OH)ₓI_{z}. R is an organo ligand with one or more carbon atoms and wherein the organo ligand comprises an alkyl, an aryl, an alkenyl, or a cycloalkyl group with 1-31 carbon atoms optionally substituted with one or more heteroatoms, 0<x+z<3, and 0.01<z<0.5.

In further aspects, the invention pertains to a method for synthesizing an organo tin iodide composition, the method comprising reacting RSn(OR′)₃ with SnI₂ in an inert solvent to form a mixture of reaction products comprising RSn(OR′)₃₋ₓIₓ, 0<x<3, and a Sn(II) byproduct, wherein RSn(OR′)₃₋ₓIₓ represents a mixture of RSn(OR′)₃, RSn(OR′)₂I, RSn(OR′)I₂, RSnI₃, in relative amounts to give x as the average number of I ligands, wherein R is an organo ligand comprising an alkyl, an aryl, an alkenyl, or a cycloalkyl group with 1-31 carbon atoms optionally substituted with one or more heteroatoms and/or unsaturated/aromatic groups and with a carbon atom bound to the tin, and R′ is an organo group with 1 to 10 carbon atoms.

### DETAILED DESCRIPTION OF THE INVENTION

Organotin compositions having partially hydrolysable iodo ligands can enable the formation of iodine-enhanced organotin oxide hydroxide photoresist films that can provide for radiation-patternable films with high EUV absorption, allowing the films to be effectively patterned with EUV radiation at low doses. The presence of the partially hydrolysable iodo ligands in the organotin precursor compositions results in the formation of organotin oxide hydroxide photoresist films having incorporated iodine atoms that can improve the absorption of EUV photons and therefore reduce the dose needed to effectively pattern the photoresist. Synthesis techniques are described to introduce the iodine ligands bound to the tin and replacing a fraction of other hydrolysable ligands. It has also been found that inclusion of an ammonium-based iodide can also supply iodine into the film, which may or may not ligate to the tin, which seems to involve integration of iodine into the oxo-hydroxo network. Regardless of the approach for introduction of the iodine into the film, the iodine in the film can be referred to as incorporated iodine. The incorporation of iodine into the coatings can reduce the thermal stability of Sn—R moieties in the deposited coating which can lower radiation dose for patterning without significant compromises to pattern quality. For convenience, the organotin compositions with iodide ligands or incorporated ammonium-based iodide or mixtures thereof can be collectively referred to as iodide supplying organotin compositions. The iodine containing compounds may be suitable for either solution based deposition and/or vapor based deposition. The organo tin oxo-hydroxo-iodo materials are suitable for negative tone and positive tone radiation lithography based on suitable pattern development.

Metal oxide photoresists (MOR) are a promising new class of materials, especially for use in EUV lithography. These photoresists generally comprise metal atoms with radiation sensitive ligands that enable the radiation-induced formation of insoluble metal oxides after exposure to EUV radiation. In particular, MOR compositions based on organotin materials are generally understood to operate based on the radiation-induced cleavage of tin-carbon bonds which induces both a polarity change (e.g., hydrophobic to hydrophilic) and a density change (e.g., low density organotin matrix to higher density more closely resembling a tin oxide matrix) that enables selective removal of either the exposed material or the unexposed material during a positive or negative development process, respectively. Owing to the metal elements, one advantage of metal oxide photoresists is their relatively high absorbance of EUV wavelengths compared to conventional polymer-based materials, which are generally comprised of atoms with low EUV absorption cross-sections, such as carbon, hydrogen, and oxygen. The iodide supplying organotin compositions described herein can further improve the EUV absorbance of the photoresist material due to the higher EUV absorption cross-section of iodine relative to Sn, C, O, and H, therefore improving the sensitivity of the photoresist which, in turn, can reduce the dose needed to effectively pattern the photoresist and can reduce the cost of manufacturing. The iodine is generally present in a −1 oxidation state (I⁻) and can be referred to as iodide, although herein iodine may be used to generally refer to iodine in its various forms, including but not limited to −1 oxidation state, without specific reference to any particular state.

Organometallic materials, particularly those based on organotin compositions, have been shown to be high-performance photoresists that enable patterning of high-resolution and high-fidelity patterns. Organotin photoresists have been broadly described in U.S. Pat. No. 9,310,684 to Meyers et al., entitled “Organometallic Solution Based High Resolution Patterning Compositions,” in U.S. Pat. No. 10,642,153 to Meyers et al., entitled “Organometallic Solution Based High Resolution Patterning Compositions and Corresponding Methods,” and in U.S. Pat. No. 10,732,505 to Meyers et al., entitled “Organotin Oxide Hydroxide Patterning Compositions, Precursors, and Patterning”, all of which are incorporated herein by reference. To the extent that radiation dose can be reduced without compromising patterning performance, process times can be reduced since dose effectively correlates with irradiation time, so a reduction in dose can increase throughput and efficiencies of capital equipment use.

In general, these organotin photoresist materials are deposited as coatings formed from precursors, the coating comprising Sn atoms associated in an oxo-hydroxo network through Sn—OH and Sn—O—Sn bonds along with intact Sn—C bonds associated with the organo ligands. The deposition can be performed as a solution deposition with a solvent or a vapor deposition. Generally, the precursors comprise hydrolysable ligands that hydrolyze during deposition and/or post deposition to replace the hydrolysable ligands with oxo-hydroxo ligands. While not wanting to be limited by theory, the intact Sn—C bonds can prevent extended dense network formation, and thus the as-deposited materials, hydrolyzed to form the oxo-hydroxo network, generally are soluble in suitable organic solvents and developers. Exposure of organotin coatings to appropriate radiation sources, such as extreme ultraviolet (EUV), ultraviolet (UV), electron beams, and the like, can result in cleavage of the Sn—C bonds and allow for further densification of the exposed area, decreasing solubility to a negative-tone liquid developer composition or susceptibility to removal by a gaseous or plasma developer composition, thereby generating a solubility and/or etch resistance contrast between exposed and unexposed regions. In this way, a physical pattern can be realized after development. The irradiated material becomes more hydrophilic, which can make the material suitable to certain developers for positive tone development, which can be based on maintained good contrast between the radiation exposed and non-exposed material.

As used herein, and as generally consistent with usage in this field, “organotin”, “hydrocarbyl tin”, and “alkyl tin” terms can be used interchangeably with the same scope, and likewise “monoalkyl” can be used interchangeably with “monoorgano” or “monohydrocarbyl”. The “alkyl” (i.e., “organo”) ligands suggest bonding to the tin via Sn—C bonds wherein the carbon is generally sp³ or sp² hybridized and forms a bond that is generally not hydrolysable through contact with water. The “alkyl” group can optionally have internal unsaturated bonds and/or heteroatoms, i.e., distinct from carbon and hydrogen, that are not involved in bonding with the tin. A chemical group bonded to a metal atom is generally referred to as a ligand in the art. A reference to a “hydrolysable ligand” generally refers to a ligand bound to the Sn with a hydrolysable bond. In some embodiments, the hydrolysable ligand can be an alkoxide ligand which is bound to Sn at an oxygen atom with an organo substituent on the oxygen (e.g., —OR′ wherein R′ is an organo group having from 1 to 10 carbon atoms and optionally substituted with one or more unsaturated carbon-carbon bonds and/or heteroatoms. In some embodiments, the hydrolysable ligand is an amide ligand which is bound to Sn at a nitrogen atom with an organo substituent(s) on the nitrogen (e.g., —NR¹R² wherein R¹ and R² are independently organo groups having from 1 to 10 carbon atoms and optionally substituted with one or more unsaturated carbon-carbon bonds and/or heteroatoms). Synthesis methods have been developed to yield monoalkyl tin trialkoxides in high yield and with low concentration (non-tin) metal and low concentration polyorganotin (i.e., polyhydrocarbyl, e.g., dialkyltin, trialkyltin) contaminants following straightforward purification. These compounds can be used for the iodine-based compositions such that these purities can be carried forward under appropriate process conditions.

As described herein, organotin compositions having iodo ligands can be used to form a radiation patternable tin oxo-hydroxo coating material having incorporated iodine (i.e., an oxo-hydroxo-iodo coating material). The organotin iodo-alkoxide compositions described herein comprise iodide ligands directly bonded to tin atoms via Sn—I bonds, which is distinct from prior art compounds wherein iodine atoms are incorporated as substituents within organic ligands (iodoalkyl groups) that are bonded to tin via Sn—C bonds. While not wanting to be limited by theory, it is believed that the tin-iodide bonds are partially hydrolysable such that upon hydrolysis, for example during the deposition process to form photoresist films, the formation of an iodine-enhanced organotin oxide hydroxide network, represented by the formula RSnO_{3/2-x/2-z/2}(OH)ₓI_{z} wherein R is an organo group, z>0, and 0<x+z<3) is achieved. In general, a reference to a formula representation is a stoichiometry unless there is reference to a specific compound or otherwise indicated. Partial hydrolysis of the tin-halide bonds with atmospheric water has been previously described in, for example in Kenane et al., Inorg. Chem. 2020, 59, 6, 3934-3941, incorporated herein by reference, which describes the partial hydrolysis of butyltin trichloride with atmospheric water to form chloride-containing hydrolysis products. The direct Sn—I bond in the present compositions provides partial hydrolyzability that enables controlled incorporation of iodine into the oxide hydroxide network, which is not achievable with iodoalkyl ligands where the iodine is covalently bound within the organic structure. The partial hydrolysis of the organotin-iodine bonds of the organotin iodo-alkoxide compositions described herein can enable the incorporation of iodine, generally as iodide ions, into the oxide hydroxide network, thereby increasing the EUV absorption of the photoresist film.

In obtaining desirable patterning results, there are tradeoffs with respect to the photoresist properties. If radiation doses can be reduced, process timing in expensive EUV irradiation chambers can be reduced, which allows increased throughput through the apparatus and improved economic feasibility of device manufacturing. In order to obtain fine patterns with low defectivity, the chemical contrast between the irradiated (exposed) and non-irradiated (unexposed) areas of the photoresist should be high. A goal can be then to lower the dose required to generate sufficient chemical contrast such that high-fidelity patterns with low line edge roughness can be achieved. In general, a lowering of thermal stability correlates with a lower radiation dose needed to transform the resist to a less hydrophobic and/or more dense form and thereby creating chemical contrast between irradiated and non-irradiated resist material. Generally, iodide ligands are observed to lower thermal stability of the binding of the organo ligands to tin, but iodine and its iodide ion also are strong EUV absorbers, which also contributes to lowering of radiation dose. While not wanting to be limited by theory, the presence of iodide ions would seem to affect the oxo-hydroxo network to lower thermal stability and correspondingly lower dose requirements in some cases. This effect seems to carry forward for all incorporated iodine, whether or not the iodide is provided as a precursor compound with a covalently bound iodide ligand or introduced into the material as an ammonium-based salt. It has also been found that blends of organotin photoresist precursors compounds can be effective to adjust the properties of the resist to meet specific objectives. The availability of the resist with the iodide ligand or species provides another dimension of composition adjustment to achieve desired performance.

In the relevant embodiments, the organotin photoresist precursor compositions having iodo ligands generally comprise hydrolytically sensitive organotin species represented by the formula: RSnL₃₋ₓIₓ, wherein x=1, 2, or 3, and L is a ligand that forms a hydrolysable bond with the Sn, such as a dialkylamide (—NR′₂), an alkoxide (—OR′), an acetylide (—C≡CR′), a carboxylate (—COOR′), and/or the like, wherein R′ is a hydrocarbyl group having from 1 to 10 carbon atoms and optional heteroatoms and/or unsaturated carbon-carbon bonds. In some embodiments, the organotin photoresist precursor compositions having iodo ligands are generally iodo or iodo-alkoxo species that can be represented by the formula RSn(OR′)₃₋ₓIₓ, where x=1, 2, or 3. The R group, alternatively referred to as the organo ligand, generally has from 1 to 31 carbon atoms with 3 to 31 carbon atoms for the secondary-bonded carbon atom and 4 to 31 carbon atoms for the tertiary-bonded carbon atom embodiments, for example, methyl, ethyl, propyl, butyl, propenyl, butenyl, pentenyl, isomers thereof, and branched alkyl. In particular, branched alkyl ligands represented by R¹R²R³C where R¹ and R² are independently an alkyl group with 1-10 carbon atoms, and R³ is hydrogen or an alkyl group with 1-10 carbon atoms. In some embodiments R¹ and R² can form a cyclic alkyl moiety, and R³ may also join the other groups in a cyclic moiety. Suitable branched alkyl ligands can be, for example, isopropyl (R¹ and R² are methyl and R³ is hydrogen), tert-butyl (R¹, R² and R³ are methyl), tert-amyl (R¹ and R² are methyl and R³ is —CHCH₃), sec-butyl (R¹ is methyl, R² is —CHCH₃, and R³ is hydrogen), cyclohexyl, cyclopentyl, cyclobutyl, and cyclopropyl. Examples of suitable cyclic groups include, for example, 1-adamantyl (—C(CH₂)₃(CH)₃(CH₂)₃ or tricyclo(3.3.1.13,7) decane bonded to the metal at a tertiary carbon) and 2-adamantyl (—CH(CH)₂(CH₂)₄(CH)₂(CH₂) or tricyclo(3.3.1.13,7) decane bonded to the metal at a secondary carbon). In other embodiments organo groups may include aryl, or alkenyl groups, for example benzyl, allyl, or alkynyl groups. In other embodiments the organo ligand R may include any group consisting solely of C and H, and containing 1-31 carbon atoms. For example: linear or branched alkyl (ⁱPr, ^{t}Bu, Me, ⁿBu), cyclo-alkyl (cyclo-propyl, cyclo-butyl, cyclo-pentyl), olefinic (alkenyl, aryl, allylic), or alkynyl groups, or combinations thereof. In further embodiments suitable R-groups may include organo groups substituted with hetero-atom functional groups selected from cyano, thio, silyl, ether, keto, ester, or halogenated groups or combinations thereof. In some embodiments, R can be a ligand with one or more carbon atoms optionally substituted with one of more heteroatoms selected from the group consisting of O, S, Se, Te, Si, Ge, Sn, F, and I. As generally used in the art, organo, alkyl and hydrocarbyl can be used interchangeably in reference to ligands without restricting incorporation of unsaturated bonds or heteroatoms.

In some embodiments, R can be an organic ligand comprising an acetal group represented by the formula (OR⁴)(OR³)R²CR¹, wherein R¹ is a substituted or unsubstituted hydrocarbyl group having from 1 to 15 carbon atoms and a Sn—C bond, R² is hydrogen or a substituted or unsubstituted hydrocarbyl group having from 1 to carbon atoms, wherein R³ and R⁴ are independently substituted or unsubstituted hydrocarbyl groups having 1 to 4 carbon atoms or wherein R³ and R⁴ collectively form a bridging structure —OR⁵O—(R⁵═R³+R⁴) where R⁵ is a hydrocarbyl group having 1 to 10 carbon atoms and forms a cyclic linkage between the acetal O atoms. As used presently in the art, acetal refers to either a traditional acetal group or a ketal group. A precursor acetyl ligand 2-methyl-2-(3-propyl)1,3-dioxolane (CH₃(CO₂CH₂CH₂) CH₂CH₂CH₂—)) is exemplified in a precursor blend. Organotin compositions comprising acetal ligands have previously been disclosed by Applicant in published U.S. Patent Application No. 2025/0074930 to Marwitz, et al. entitled ‘Organotin Compositions Having Ligands With Acetal Functional Groups, Patterning Compositions With Organotin Blends And Positive Tone Patterning’, which is hereby incorporated by reference. The previous results with the acetal group ligands demonstrated desirable positive-tone patterning.

Each R group individually and generally can have from 1 to 31 carbon atoms with 3 to 31 carbon atoms for the group with a secondary-bonded carbon atom and 4 to 31 carbon atoms for the group with a tertiary-bonded carbon atom, optionally with unsaturated or aromatic carbon bonds. Groups with unsaturated carbon bonds and no hetero atoms can be described as a branched or linear group with an overall stoichiometry of CₙH₂₍ₙ₋₁₎₊₃, n=1 to 31. In particular, branched or cyclo alkyl (unsaturated) ligands can be desirable for some patterning compositions. The formation of the oxo-hydroxo coating material can comprise deposition of one or more tin composition(s) with hydrolysable bonds, such as RSnL₃, where L is a hydrolysable ligand, such as an alkoxide (OR′), a dialkyl amine (NR′₂), an acetylide (C≡CR′), or other suitable hydrolysable ligand. The hydrolysable ligands can be hydrolyzed to form the oxo-hydroxo network during deposition of the coating and/or in the coating following deposition, i.e., completing the hydrolysis after deposition. Applicant has developed methodologies to efficiently and effectively form a wide range of patterning compositions with different R groups, optionally with various hetero atoms, with C—Sn bonds, as described further in published U.S. patent application No. 202200064192 to Edson et al. (herein the '192 application), entitled “Methods to Produce Organotin Compositions With Convenient Ligand Providing Reactants,” incorporated herein by reference.

The synthesis of alkyltin di-iodo dialkylamide, alkyltin iodo di (dialkylamide), or dialkyltin iodo dialkyamide compounds are described in U.S. Pat. No. 12,384,805 to Kwone et al. (hereinafter the '805 patent), entitled “Iodide-Containing Metal Compound and Composition for Depositing Thin Film Including the Same,” incorporated herein by reference. The '805 patent teaches plasma enhanced atomic layer deposition to deposit a coating. In some embodiments, oxygen or ozone was used as a reaction gas, and argon was used as a purge. The resulting films were a tin oxide, and no carbon, nitrogen or iodine was detected in the coating. In alternative embodiments, the '805 patent discloses using carbon dioxide as a reactant gas, and the resulting film has 5% carbon and 10% iodine. In a further embodiment, the '805 patent discloses using water as the reactant gas, and again the resulting film had 5% carbon and 10% iodine. These films were not characterized further with respect to the nature of the bonding in the films. Embodiments of films deposited with carbon dioxide were patterned using EUV radiation. In contrast, the present disclosure teaches more versatile synthesis and processing approaches that expands the compositions to a wider range of stoichiometries with the ability to engineer a range of thin films for patterning. Since the '805 patent teaches vapor deposition of the purified compounds, the organotin compounds with iodo ligands have appropriate vapor pressures for vapor deposition and can correspondingly be deposited without a plasma under hydrolyzing conditions. Such an approach for the currently synthesized compositions is discussed further below.

Furthermore, the organotin compositions having partially hydrolysable iodo ligands can generally include mixtures of distinct iodo-alkoxo species according to the formula: RSn(OR′)₃₋ₓIₓ where each distinct species corresponds to formula with a different value of x. The mixtures, or compositions with x<3, can then undergo redistribution of alkoxide (or other hydrolysable ligands) and iodo ligands to afford an overall distribution of distinct species that is dependent upon the initial concentrations of and ratios between the starting compounds. The precursor blend mixture of various iodo and alkoxide species can be specifically designed to undergo a controlled redistribution to give a desired distribution of iodo-alkoxo species. Mixtures of compounds having the general formula RSnL₃, where R is an organic group and Lis a hydrolysable ligand or partially hydrolysable ligand as defined above, can undergo a process known as redistribution or ligand exchange. This phenomenon occurs when two or more RSnL₃ compounds having different L ligands are mixed together, resulting in a redistribution of the L ligands among the tin centers to afford an overall composition with a distinct distribution of species distinct concentrations that are depending on the stoichiometry of the initial mixture. For example, an initial precursor blend mixture of RSn(OR′)₃ and RSnI₃ can undergo ligand exchange reactions that can lead to the formation of a mixture of two or more distinct species having both alkoxide and iodide ligands. The alkoxide (OR′) and iodide (I) ligands can redistribute between the tin centers, producing compounds such as RSn(OR′)₂I and RSn(OR′)I₂ to produce a distribution of species in varying concentrations and having an overall composition that can be represented by the general formula RSn(OR′)₃₋ₓIₓ. The redistribution process results in an equilibrium complex mixture of distinct RSn(OR′)₃₋ₓIₓ species with different ratios of alkoxide and iodide ligands, i.e., different values of x, in different concentrations. A person of the ordinary skill in the art will understand that while the overall precursor blend composition comprises multiple distinct RSn(OR′)₃₋ₓIₓ species having integer values for x from 0 to 3 and in different concentrations, the overall blend composition itself can be represented as a stoichiometry by the general formula RSn(OR′)₃₋ₓIₓ where 0<x<3 based on weighted averages of each constituent and x is not necessarily an integer. In some embodiments, the overall blend composition can have x values from about 0.01 to about 3, in some embodiments from about 0.05 to about 2.0, and in some embodiments from about 0.1 to about 1.0. A person of ordinary skill in the art will recognize that additional values for x within the explicit ranges above are contemplated and are within the present disclosure.

It has also been found useful to use blends of organo groups bound to the tin when forming radiation patternable films and corresponding precursor solutions. If a composition is formed also with R′SnL′₃, where R′ is different from R and L′ may or may not be different from L, is included in the precursor solution, then the L′ may also exchange with iodo ligands to form an overall equilibrium. In some embodiments, the organotin composition can comprise an initial blend of two or more RSn(OR′)₃₋ₓIₓ compounds, each having a distinct R group. In some embodiments, the organotin composition can comprise an initial blend of R^{a}Sn(OR^{b})₃₋ₓIₓ and a R^{c}Sn(OR^{d})₃ compound where R^{a} and R^{c} are different organo groups R as defined above and R^{b} and R^{d} may or may not be different organo groups R′ as defined above.

As shown in the Examples herein, the final composition of the mixture can be specifically achieved by specifically controlling the initial concentrations of the starting compounds. The specific final composition of the mixture can be tailored to achieve a desired equilibrium-driven distribution of iodide, alkoxide, and iodo-alkoxide species. The initial mixture of organotin iodo-alkoxide compounds and organotin alkoxide compounds can be described as a molar ratio between the two compositions. In some embodiments, the initial molar ratio of the organotin iodo-alkoxide compounds to the organotin alkoxide compounds can be from about 1:100 to about 1:2, in some embodiments from about 1:50 to about 1:1.5, from about 1:10 to about 1:1.2, from about 1:5 to about 1:1.1, from about 1:3 to about 1:1.1, and from about 1:2.5 to about 1;1.1, in further embodiments. The initial mixture of organotin iodo-alkoxide compounds and organotin alkoxide compounds can also be equivalently described as a molar percentage of the organotin iodo-alkoxide composition relative to the total tin concentration. In some embodiments, the organotin iodo-alkoxide composition can be present in an initial molar percentage of at least about 1% to about 70% of the total Sn concentration, in some embodiments of at least about 2% to about 60% of the total Sn concentration, at least about 10% to about 55%, at least about 20% to about 54%, at least about 25% to about 52%, and at least about 30% to about 50% of the total Sn concentration in further embodiments. A person of ordinary skill in the art will recognize that additional molar ratios and percentages within the explicit ranges above are contemplated and are within the present disclosure.

Iodine atoms are generally useful to include in the organotin photoresist composition for a number of reasons. The inclusion of iodine atoms in an organotin photoresist composition can be achieved through the inclusion of a tin-iodo compound or an ammonium-based iodide additive. First, iodine can increase the EUV absorption of the photoresist composition, which can lead to lower patterning doses needed to achieve desirable patterning. Iodine has a relatively high EUV absorption cross section to 13.5 nm EUV radiation, a wavelength that is commonly utilized in commercially available EUV tools. The introduction of iodine atoms into the composition can be achieved either through inclusion of iodine heteroatoms within the organo ligands (R groups) bound to the tin atoms, by introducing partially hydrolysable iodo ligands bound directly to the tin or by including a iodide salt additive, which may or may not result in the iodide ion being bound to a tin. The former strategy of introducing iodine heteroatoms within the organo ligands to form an iodoalkyl ligands can require complicated synthetic pathways in which the iodoalkyl radical requires attachment to the Sn atoms. Some of these synthetic pathways have been previously described in the '192 application, along with EUV lithographic patterning using the compounds.

Conversely, partially hydrolysable tin-iodine bonds can be formed and used in an organotin precursor in conjunction with desirable organo ligands, such as those having secondary or tertiary alpha carbons. During deposition, hydrolysis and condensation can occur to form result in the formation of a radiation-patternable film comprising an organometallic oxide hydroxide iodide network represented by the formula RSnO_{3/2-x/2-z/2}(OH)ₓI_{z}, where 0<x+z<3 and z>0, and where the iodide atoms are distributed and incorporated throughout the solid film. While the alkoxide ligands are found to be removed by hydrolysis, results demonstrate that some of the iodine ligands remain. If a portion of the iodine is hydrolyzed and cleaved form the tin, cleaved iodide ions may form hydrogen iodide, which is a gas which may desorb from the material or may bind into the oxo-hydroxo network via hydrogen bonding or similar intermolecular interaction. As noted above, z can be reduced through a mixture with a non-iodinated precursor with the same R group as well as loss of I through hydrolysis. This partial hydrolyzability allows the iodine content in the final coating to be tuned through processing conditions (e.g., bake temperature and/or bake duration) in addition to precursor composition. As noted below, species with different R′ organo ligands can similarly be introduced to form a radiation patternable film with correspondingly adjusted properties. In some embodiments of particular interest, z can have a range from an upper limit of 0.5, in further embodiments of about 0.4, in other embodiments of about 0.3, and in additional embodiments of about 0.25 in a range with any one upper limit value of which to a lower limit value of about 0.01, in further embodiments of about 0.025, in other embodiments of about 0.05 and in additional embodiments of about 0.1. A person of ordinary skill in the art will recognize that additional ranges within the explicit compositional ranges above are contemplated and are within the present disclosure.

Under process conditions used, at most a portion of the iodine is hydrolyzed and removed from the material. Elemental analysis establishes the maintenance of iodine in the material of the deposited and dried films. The inclusion of iodine atoms in the photoresist composition offers several advantages. Iodine has a relatively high absorption cross-section for EUV radiation, which can significantly enhance the overall EUV absorbance of the photoresist material, enabling more efficient use of the incident radiation, and therefore leading to improved sensitivity and lower dose requirements for patterning. Furthermore, the introduction of iodide ions through the formation of tin-iodine bonds allows for greater flexibility in the selection of desirable organo ligands, such as organo ligands having secondary or tertiary alpha carbons, relative to using compounds having iodine functionality in the R group. These desirable organo ligands can be incorporated alongside the iodine ligands without the need for more complex iodoalkyl synthesis. Therefore, the photoresist can be tailored to have specific properties such as enhanced sensitivity and enhanced contrast. Also, as noted herein, iodide ions can be introduced in additives, which can provide a further pathway for introducing iodide ions into the patterning material. The use of additives as the route for iodide introduction can potentially be convenient alternatives that do not rely on changes to the synthesis of the tin precursor compositions, and the use of additives is described further below,

Another advantage of incorporating the iodide atoms within the oxide hydroxide network is that the presence of iodine in the photoresist films allows for the thermally induced cleavage of tin-carbon bonds at lower processing temperatures. As shown in the Examples below, the thermal decomposition temperature of the tin-organo group bonds (Sn—R) of organotin films can be shown via Fourier transform infrared spectroscopy (FTIR) on thermally treated films to be significantly lowered in films prepared from iodine-rich compositions. The reduction of thermal decomposition temperatures can provide for lower patterning doses because the irradiated material can be rendered insoluble with less radiation dose and appropriate thermal processing, such as during a PEB. The enhanced EUV adsorption due to the presence of iodine along with the changes in the Sn—R bond strengths both can contribute to a lowering of irradiation dose required for effective patterning. Generally, higher PEB temperatures can reduce the dose requirement at the expense of pattern quality (by appropriate metrics such as LCDU (local critical dimension uniformity), LWR (line width roughness), LER (line edge roughness), and the like). The compositions described herein can enable lower patterning doses without significant compromises to pattern quality. Roughness features are generally defined as a 3 sigma statistical variation. Specifically, LCDU for holes refers to is the local hole-to-hole variation of the critical dimension (CD), evaluated as a 3 sigma value from the distribution of CD. For evaluation, see published U.S. patent application 2016/0379824 to Wise et al., entitled “Low Roughness EUV Lithography,” incorporated herein by reference. In some embodiments, the radiation patternable organotin oxo-hydroxo-iodo films can offer both superior patterning doses and pattern quality, which can provide a significant patterning advantage.

Applicant has discovered, as exemplified below, that in some embodiments with negative tone patterning, the effect of iodide inclusion can be dependent on the photoresist composition. In some embodiments, the inclusion of iodine into the resist composition through the addition of an ammonium-based iodide additive can decrease the radiation sensitivity for an organotin composition comprising secondary organic ligands and increase the sensitivity for an organotin composition comprising a blend of primary and tertiary alkyl ligands. These results are not yet understood with respect to which features may result in the unexpected increase of dose, although it has been discovered by Applicant that the addition of an ammonium-based iodide additive can generally decrease the patterning dose for an organotin photoresist composition. Thus, the organotin precursor identity, ammonium-based iodide additive, and concentration of the additive can be appropriately selected to realize a dose reduction. Such evaluation and selection of parameters would be considered routine in the art of lithography, given established practices of adjusting formulation and process parameters balancing complex effects to refine the performance of photoresists.

The organotin iodo compositions can be particularly useful for positive tone patterning processes, wherein the exposed regions are removed during development to yield a positive tone pattern. While not wanting to be limited by theory, it is believed that the inclusion of iodine, such as through the addition of an ammonium-based iodide additive, in the photoresist coating can reduce the thermolysis temperature of the organic ligands. Generally, in positive tone patterning with MORs the exposure dose and thermal processing conditions can be selected to modulate the solubility contrast between exposed and unexposed regions in subsequent development steps.

Without being limited by theory, it is believed that two concurrent mechanisms can occur during irradiative exposure and subsequent thermal processing of the organotin-based coatings. The first is a dealkylation mechanism wherein Sn—C bonds are cleaved, thereby eliminating some organic ligands from the tin oxo-hydroxo matrix and increasing the material's solubility to a positive tone developer, for example an aqueous developer, an aqueous base, alkaline developer, or other developer suitable for positive tone development of metal-oxide based resists, and decreasing the material's solubility to a negative tone developer, for example, 2-heptanone. The second is a condensation mechanism wherein Sn—O—Sn bridges are formed, thereby increasing the metal oxide character of the coating which means it is denser and less soluble in a suitable aqueous developer solution for positive tone development. A goal of positive tone patterning can be to modulate the exposure dose and PEB temperatures and durations to achieve dealkylation sufficient to render the exposed region soluble in the positive tone developer composition without causing excessive condensation which can render the entire coating relatively insoluble to the positive developer composition. Although the dealkylation and condensation mechanisms can proceed concurrently and can even exhibit kinetic coupling in some instances, the respective extents of each dealkylation and condensation can be modulated somewhat independently to affect patterning performance through the incorporation of iodide ions into the material, such as through inclusion of an ammonium-based iodide additive.

To the extent that the incorporation of iodide ions into the material, such as through adding the ammonium-based iodide additive, can decrease the thermolysis temperature of the Sn—C bonds within the organotin based coating, thorough and sufficient dealkylation can be achieved at lower PEB temperatures. The use of a lower PEB temperature can limit the extent of thermolysis driven condensation, which as suggested by data in the examples, can improve the solubility contrast between exposed and unexposed regions in a positive tone developer. The inclusion of iodide ions, such as using ammonium-based iodide additives described herein, can provide a method of achieving sufficient dealkylation at a lower dose and/or PEB temperature without sacrificing pattern quality.

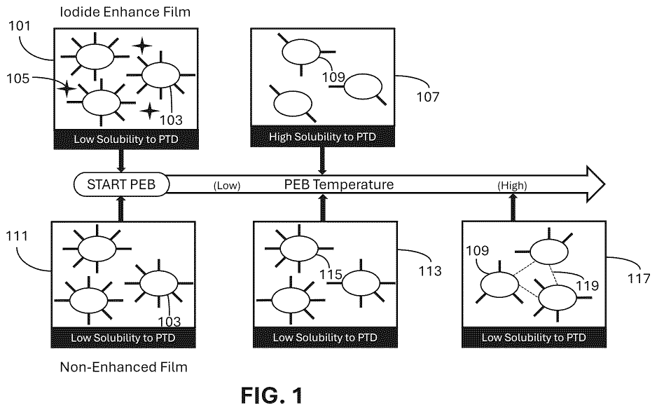

While not wanting to be limited by theory, FIG. 1 illustrates proposed structures of radiation exposed tin-based films at varying PEB temperatures. An iodine enhanced organotin-based material 101 comprises alkylated organotin species 103 and iodine 105. A comparative non-enhanced organotin-based material 111 comprises alkylated organotin species 103. While not wanting to be limited by theory, the iodine can decrease the thermolysis temperature of the organic ligands. The iodine enhanced material is subjected to a relatively low PEB temperature and undergoes significant dealkylation to yield an iodine enhanced lower temperature baked material 107 comprising sufficiently dealkylated organotin species 109. The iodine enhanced lower temperature baked material has high solubility to a positive tone developer composition. Contrastingly, the non-enhanced material is subjected to the same relatively low PEB temperature and undergoes less dealkylation to yield a non-enhanced lower temperature baked material 113 comprising insufficiently dealkylated organotin species 115. The non-enhanced lower temperature baked material retains a low solubility to a positive tone developer composition. At the same lower PEB temperature, the iodine enhanced material generates higher contrast between the exposed and unexposed regions than the non-enhanced material. The non-enhanced material is subjected to a higher temperature PEB to induce sufficient dealkylation and yield a non-enhanced high temperature baked material 117. Although the non-enhanced higher temperature baked material undergoes significant dealkylation to comprise sufficiently dealkylated organotin material 109, significant crosslinking 119 forms at the high PEB temperature. The non-enhanced higher temperature baked material is crosslinked and dense and thus retains low solubility to a positive tone developer composition and limited contrast between the exposed and unexposed region is generated. The structures schematically depicted in FIG. 1 are intended to be illustrative and may not correspond to the actual chemical structures of the tin-based films. While not wanting to be limited by theory, the figures are intended to convey proposed mechanistic distinctions between iodide enhanced and non-enhanced organotin materials.

A noted above, iodide ions can be introduced as ligands to tin precursor compounds or through inclusion in additives. In embodiments involving precursors with iodide ligands, the iodo-alkoxo precursor compounds can be synthesized via redistribution of organotin triiodide, RSnI₃. RSnI₃ compounds can generally be synthesized via iodination of a tetraorgano RSnPh₃ (Ph=phenyl) precursor by reaction with elemental iodine, I₂, according to reaction 1, where R can be any of the organo R ligands described above.

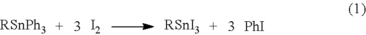

The tetraorgano RSnPh₃ compound can be synthesized, for example, through a Grignard reaction, such as between triphenyltin chloride as described in J. Organomet. Chem. (1975), 97(1), 45-9 and J. chem. Soc. Dalton trans. 1990, 2643. In some embodiments, the iodination reaction can be conducted at temperatures from about 20° C. to about 200° C., in additional embodiments from about 50° C. to about 150° C., and in further embodiments from about 75° C. to about 125° C. 25 The iodination reaction can be conducted for at least about 1 hour in some embodiments, at least about 8 hours in some embodiments, and from about 10 hours to about 48 hours in other embodiments. The product RSnI₃ can be purified and separated from the PhI byproduct by distillation. The Examples herein describe the synthesis of iPrSnI₃. A person of ordinary skill in the art will recognize that additional ranges of reaction temperatures and reaction times within the explicit ranges above are contemplated and are within the present disclosure.

The RSnI₃ compounds can be used to form a range of precursor compositions. As noted above, the iodo ligands are exchangeable with other hydrolysable ligands. This mechanism can be used to synthesize various precursor blends through the advantageous use of the exchangeable ligands. The relative amounts of I and Sn can be set by the selection of the amounts of the reactants whether or not they exchange subsequently. So while the specific species in solution can vary over time, the relative total amounts of the iodine and tin, present as their ions, can be set. Suitable values for the iodine-tin ratios are discussed below.

In some embodiments, the iodo-alkoxo precursor compositions can be synthesized by a distribution reaction between RSn(OR′)₃ and SnI₂ where a distribution of product species of the formula RSn(OR′)₃₋ₓIₓ (e.g., RSn(OR′)₂I and RSn(OR′)I₂, corresponding to x=1 and x=2 species, respectively) are produced in concentrations dependent upon the initial amounts of the reactants. For example, an initial reactant mixture having a relatively higher initial amount of RSn(OR′)₃ can result in a relatively higher predominance of x=1 species whereas an initial stoichiometry having a relatively higher initial amount of SnI₂ can result in a relatively higher predominance of x=2 species. The reaction can generally be carried out in any suitable organic solvent and the solvent can be selected to be inert to the reaction products, inputs, and intermediates. The SnI₂ is generally sparingly soluble in the solvent, but it is consumed as the reaction proceeds. Conveniently, in some embodiments an Sn(II) byproduct formed during the reaction can be insoluble in an organic solvent phase and separated via filtration to yield a high purity, filtered reaction product. Suitable solvents include aromatic solvents. The concentrations are not necessarily significant, although the organo tin reactants should be soluble and the reaction rate may depend on the concentrations. The preparation of a mixture of compounds represented by the formula RSn(OtAmyl)₃₋ₓIₓ, where R=tert-butyl, having a distribution of x=0, 1, and 2 species is demonstrated in the Examples herein. While the iodide ligands are exchangeable, they generally remain bound to the tin species so that once the target composition is formed and at equilibrium, the relative amounts in the distribution should not fluctuate significantly. The reactant can be allowed to react for as long as is needed to achieve a desired yield and/or speciation of products, and the identity of the reactants can affect the reaction time necessary to achieve the desired yield. In some embodiments, the reactants can be allowed to react for at least 12 hours, at least 24 hours in some embodiments, and in further embodiments at least 72 hours. A reaction time of 72 hours is exemplified herein.

Regardless of the reactions used to synthesize the organotin compositions with iodo ligands, the individual compounds can be purified by distillation. Using fractional distillation, which may involve pressure reduction, a particular compound can be reasonably purified, i.e., RSn(OR′)₂I, RSn(OR′)I₂, or RSnI₃. The purified compounds can be carried forward as desired. The purification results in the neat, i.e., solvent-free, form of the compounds. It has not been established whether or not ligand exchange takes place in the purified form or at what rate if it does occur. The purified compounds may be desirably used for vapor deposition.

In relevant embodiments, the resist precursor solutions comprise one or generally more than one iodo or iodo-alkoxo precursor compositions and an organic solvent. The resist precursor composition can be conveniently specified based on tin ion molar concentration. In general, the resist precursor solution generally comprises from about 0.0025 M to about 1 M tin cation, in some embodiments from about 0.004M to about 0.9M, in further embodiments from about 0.005 M to about 0.75 M, also in some embodiments from about 0.01M to about 1M, and in additional embodiments from about 0.01 M to about 0.5 M tin cation. A person of ordinary skill in the art will recognize that additional concentration ranges and values within the explicit ranges above are contemplated and are within the present disclosure. Similarly, the solution can be characterized by the relative amount of iodo ligands.

In the preparation of the organo tin precursors with iodo ligands, it is noted above that the ligands can exchange, so the precise distribution of ligands among the organo tin species generally would achieve particular values based on the processing and specifics of the input compounds. Similarly, the results suggest that the iodo ligands remain bound to tin and do not become solvated separate from tin ligation, but this is not known with certainty. But in any case, the overall quantity of iodide ions relative to tin ions is established by the reactants, and there is no evidence of iodide removal by volatilization, such as from formation of HI. In the precursor solutions, the ratio of iodide ligand (or solvated iodide) to tin ions can be in a ratio from about 0.01:1 I relative to Sn to about 2:1 I relative to Sn in some embodiments, from about 0.05:1 I relative to Sn to about 1:1 I relative to Sn in other embodiments, and from about 0.1:1 I relative to Sn to about 0.5:1 I relative to Sn in further embodiments. In some embodiments, the lower limit of mole % I relative to Sn is no less than about 0.1 mole % I relative to Sn, no less than about 0.5 mole % I relative to Sn in some embodiments, and no less than about 1 mole % I relative to Sn in further embodiments. A person of ordinary skill in the art will recognize that additional ranges of I to Sn ratios and mole % values within the explicit ranges above are contemplated and are within the present disclosure.

In some embodiments, the iodide supplying organotin precursor compositions can comprise an ammonium-based, i.e., ammonium or alkyl ammonium, iodide compound represented by the formula NR′4I or a mixture thereof, where each of the four R′ is independently hydrogen or a linear or branched or cyclic (saturated, unsaturated or aromatic) organo group having 1 to 10 carbons and optional heteroatoms. In some embodiments, all four R′ are hydrogen and the compound is ammonium iodide. In some embodiments, all four R′ are organo groups and the compound is a quaternary ammonium iodide. In some embodiments, one to three of R′ are H and the other R′ are independently an organo group and the compound is an alkyl (organo) ammonium iodide. For quaternary ammonium iodide, the four R′ do not need to be the same as each other. Other general formula for the ammonium-based compounds are NHR′₃I, NH₂R′₂I, and NH₃R′I, in which multiple R′ in a molecule are independently selected. Some examples of suitable ammonium-based iodide compounds are ammonium iodide methylammonium iodide, diethylammonium iodide, triethylammonium iodide, anilinium iodide (C₆H₅NH₃I), and mixtures thereof. In some embodiments, the ammonium based iodide compounds can be tetramethyl ammonium iodide, tetraethyl ammonium iodide, tetrabutyl ammonium iodide, or combinations thereof. The ammonium-based iodide compound can generate iodide ligands that can coordinate and/or complex with the organotin species in the resist precursor solutions and allow for the incorporation of iodine atoms into the organotin oxide hydroxide coating upon deposition.

Various approaches can be used to form the iodide enhanced precursor solutions, and the resulting compositions may or may not be independent of the process order. It may also be unclear the particular bonding and equilibrium exhibited by the compositions, which may involve complex mixtures of constituent, but the nature of the overall composition can nevertheless be well characterized and processed accordingly without concern over the atomic scale details. In some embodiments, the ammonium-based iodide compound can be added to the photoresist solution by dissolving an appropriate mass of the compound into the photoresist solution composition. These solutions can be formed at an initial concentration, and subsequently diluted to achieve a desired concentration for deposition. Once formed in solution, the precursor compositions can evolve to a distribution of constituents that may remain relatively constant over reasonable time frames. The ammonium-based iodide compounds and solvents can be selected appropriately to achieve desired solubility for a tin precursor concentration. In some embodiments, the ammonium-based iodide compound can be first dissolved into an appropriate solvent to form an ammonium-based iodide solution that can then be added to the photoresist solution composition. The ammonium-based iodide compound can similarly be added to a concentrated precursor solution comprising one or more organotin alkoxide compounds in a solvent to form a concentrated solution which can then be diluted in an appropriate solvent or blended with another precursor solution, if desired. Again, these solutions can be formed at an initial concentration and subsequently diluted. Achievement of dissolved ammonium-based iodide can be allowed to take place over an extended period of time, and the initial mixtures can be appropriately stirred for a sufficient period of time, such as minutes, hours, overnight or longer, to complete the dissolving process.

In embodiments wherein the iodo-alkoxo composition comprises an ammonium-based, i.e. ammonium or alkyl (organo) ammonium, iodide compound, the concentration of the ammonium-based iodide compound can be represented as mole percentage of NR′₄I added relative to the total Sn concentration. In some embodiments, the upper limit of mole % of NR′₄I relative to total Sn concentration is no more than about 50 mole % relative to Sn, no more than about 25 mole % relative to Sn in some embodiments, no more than about 20 mole % in other embodiments, and no more than about 15 mole % relative to Sn in further embodiments. In some embodiments, the lower limit of mole % NR′I relative to Sn is no less than about 0.1 mole % relative to Sn, no less than about 0.5 mole % relative to Sn in some embodiments, and no less than about 1 mole % relative to Sn in further embodiments. Based on a selected concentration of tin in the precursor solution, the concentration of NR′₄I follows from the tin concentration and the molar ratio. In some embodiments, the NR′₄I compounds can be in the solution at a mole ratio to tin of 0.001 to about 0.5, in further embodiments from about 0.005 to about 0.25, in some embodiments from about 0.01 to about 0.15 moles NR′₄I per mole of tin. A person of ordinary skill in the art will understand that additional ranges of mole ratios of NR′₄I per tin and mole percentages relative to the total tin concentration are contemplated and are within the present disclosure.

The ammonium ion with independently selected substituents (NR′₄⁺) can be more specifically written as NR¹′R²′R³′R⁴′⁺, where R¹′-R⁴′⁺ are independently H or an organo group with 1 to 10 carbon atoms, optionally substituted with hetero atoms or unsaturated/aromatic groups. If R¹′-R⁴′ are all H, the ammonium ion is the simple ammonium NH₄⁺, and the meaning of “ammonium” as the specific ion or the more general ion follows from the context. If all of the R′ groups are organo groups, the ion is a quaternary ammonium that does not have an available hydrogen to deprotonate. The NR¹′R²′R³′H⁺, NR¹′R²′H₂⁺ and NR¹′H₃⁺ can deprotonate to form a neutral amine, which is not available for the quaternary ammonium. As noted below, aromatic amines can function as photo acid generators or quenching agents.

As noted above, it can be desirable to have blends of precursors with two or more different “R” groups to provide desirable patterning properties for the resulting deposited radiation sensitive films, in which each “R” group is independently selected as specified above for general organotin precursors. With respect to proportions, in some embodiments, the precursor blends generally can comprise a range of a first organotin precursor from a lower limit of about 30 mol %, about 40 mol %, about 50 mol %, or 60 mol % any one of which to an upper limit value of about 55 mol %, 65 mol %, 75 mol %, 80 mol %, 85 mol %, 90 mol %, 95 mol % or 98 mol % of the first organotin precursor relative to the total moles tin in the blend. Generally, the remainder of the organotin components can be one or more additional precursors with selected relative amounts. In some embodiments, a precursor blend can comprise approximately equal molar amounts of two or more precursors. Specifically, the precursor blends can comprise a range of second organotin precursors from a lower limit of about 2 mole percent (mol %) or about 3 mol % or about 4 mol % or about 5 mol % any one of which to an upper limit value of about 20 mol % or about 30 mol % or about 35 mol %, or about 40 mol % or about 45 mol % or about 50 mol %, which can apply to a plurality of precursors. A person of ordinary skill in the art will recognize that additional ranges of individual tin precursors are contemplated and are within the present disclosure. Various blends of precursors are used in the examples below.

The organotin iodo compositions comprising mixtures of RSnL₃₋ₓIₓ species can be characterized by various analytical techniques. While other analytical techniques, such as gas chromatography mass spectroscopy (GCMS), can be used, ¹¹⁹Sn NMR spectroscopy is particularly useful for identifying and quantifying the distribution of RSnL₃₋ₓIₓ species with different x values. Each distinct species (x=0, 1, 2, 3) exhibits a characteristic chemical shift, allowing for determination of the composition. The examples below include ¹¹⁹Sn NMR spectra used to determine the distribution of iPrSn(OtAmyl)₃₋ₓIₓ compositions.

Based on the teachings above, one or more of the precursors in a precursor blend can comprise iodo ligands, which generally themselves result in blends with respect to ligand distributions. So one can envision blends with respect to at least two distinct “R” groups as well as ligand distributions ((OR′)₃₋ₓIₓ). Since iodo ligands are observed to redistribute with respect to alkoxide ligands OR′, one would expect iodide/hydrolysable ligand redistribution to also occur between RSn and R′Sn where R and R′ organic ligands and R is different from R′, but the kinetics and thermodynamics of these processes are not understood well enough to be certain of this. For example, a 50 mol % mixture each of R¹Sn(OR′)₂I and R²Sn(OR′)₃ may or may not result in the same precursor solution after a reasonable period of time as a 50 mol % mixture each of R¹Sn(OR′)₃ and R²Sn(OR′)₂I. In any case, desired iodo ligands can be introduced into one or more organo precursors in a blend of two or more different “R” groups.

In general, the precise structure of species, which may be transient, in solution is not known, but gelling is controlled to help maintain processability of the precursor solution and avoid instability. It has been found that controlling the amount of water in the precursor solution can be desirable for process uniformity without excessively sacrificing shelf life, as described further below. These concepts seem to apply equally in the presence of iodide species. In some cases, organotin photoresists can comprise cluster compositions where multiple RSn moieties are linked through Sn—O—Sn, Sn—OH—Sn, or Sn—COO—Sn bonds such as, for example, in the dodecameric “football” clusters [(RSn)₁₂O₁₄(OH)₆]²⁺ and the hexameric “drum” clusters [RSnOOCR′]₆. In some embodiments, I atoms can be incorporated or coordinated within these clusters, possibly as a ligand to the tin. These organotin compositions are generally dissolved in appropriate solvents to form organotin photoresist solutions. The use of tin dodecamer clusters for patterning is described in U.S. Pat. No. 11,392,028 to Cardineau et al., entitled “Tin Dodecamers and Radiation 20) Patternable Coatings With Strong EUV Absorption,” incorporated herein by reference.

The organotin precursor(s) can also generally be dissolved in mixtures of solvents to prepare precursor solutions. Some solvent mixtures useful for forming organotin photoresist solutions have been described in published U.S. Patent Application 2023/0143592 to Jiang et al., entitled “Stability-Enhanced Organotin Photoresist Compositions”, incorporated herein by reference. The solvent system may be selected to provide adequate solubility for both the organotin composition(s) and the ammonium-based iodide compound. In some embodiments the solvent can be an organic solvent, an alcohol or blends thereof. Generally, the solvents are at least 50 weight percent alcohols with any remaining organic solvent liquids being soluble in the alcohol, such as an alkane (such as pentane or hexane), an aromatic hydrocarbon (such as toluene), an ether (such as diethyl ether, C₂H₅OC₂H₅), an ester, or mixtures thereof. In some embodiments, the solvent is at least 90 weight percent alcohol, and the solvent can be effectively alcohol with just trace impurities of other compounds. Suitable alcohols are generally monomeric alcohols with a melting point of no more than about 10° C., such as methanol, ethanol, propanol, butanol, pentanol, hexanol, heptanol, octanol, nonanol, decanol, branched versions thereof, isomers thereof (such as 3-pentanol, 2-butanol, or 4-methyl-2-pentanol), and mixtures thereof.

It has been found that controlling the water level can result in consistent and stable precursor solutions. In particular, the water level can be adjusted, generally by addition of small amounts of water to the solvent to achieve the target water levels, generally no more than about 10,000 ppm by weight, in additional embodiments from about 300 ppm by weight to about 2500 ppm by weight, in further embodiments from about 200 ppm by weight, and in additional embodiments from about 250 ppm to about 1000 ppm by weight water. A person of ordinary skill in the art will recognize that additional ranges within the explicit ranges above are contemplated and are within the present disclosure. The use of water content adjustment is discussed further in U.S. Pat. No. 11,300,876 to Jiang et al., entitled “Stable Solutions of Monoalkyl Tin Alkoxides and Their Hydrolysis and Condensation Products,” incorporated herein by reference.

The organotin iodo-alkoxide compositions in organic solvents exhibit good stability when stored under appropriate conditions. The compositions may be stored in sealed light-opaque containers under inert atmosphere (e.g., nitrogen or argon) to minimize exposure to moisture, oxygen, and light prior to processing to form radiation-patternable films. Storage temperatures may range from about −20° C. to about 40° C., with room temperature storage being suitable for most compositions. In some embodiments, the shelf life of the compositions in solution may exceed 30 days, in further embodiments may exceed 60 days, and in additional embodiments may exceed 90 days when stored under appropriate conditions.

The stability of the compositions can be monitored by ¹¹⁹Sn NMR spectroscopy to detect any changes in the distribution of species or the formation of decomposition products. In some embodiments, the distribution of RSn(OR′)₃₋ₓIₓ remains substantially constant (within ±5% of initial values) for at least 30 days of storage, in further embodiments for at least 60 days of storage, and in additional embodiments for at least 90 days of storage.

In some embodiments, the iodide supplying or iodide enhanced organotin precursor solutions can further comprise a radical scavenging additive. The addition of a radical scavenging compound can reduce undesirable effects of radical contaminants which can increase wafer to wafer consistency amidst changes to the processing environment. To decrease deleterious effects from radicals, further additives can be included in the precursor solutions to scavenge radicals. Such additives have been shown to be beneficial, as described in published U.S. patent application 2025/0251662 to Eberle et al. (hereinafter the '662 application), entitled “Radical Scavenger Additives for Metal Oxide Based Resists and Precursor Solutions,” incorporated herein by reference. A suitable concentration of radical scavenger can depend significantly on the agent used, but generally the concentration of radical scavenger in the precursor solution can be from about 0.000025M to about 0.4M, and any subrange within this concentration range is contemplated and recognized to be in this disclosure.

Radical scavenger compounds can include, for example, H-donor radical scavengers, such as phenolic compounds and hindered amines. The phenolic compounds can be characterized by the presence of a substituted aromatic ring which can improve their ability to form relatively stable radicals after hydrogen atom transfer. In some embodiments, the H-donor radical scavenger is a hindered phenol compound having an aromatic ring substituted with an electron-donating group. In some embodiments, the H-donor radical scavenger is butylated hydroxytoluene (BHT) or 15 butylated hydroxyaniline (BHA), and more general embodiments are described in the '662 application. In some embodiments, the H-donor radical scavenger is an aromatic diol. In some embodiments, the H-donor radical scavenger is an alkoxyphenol, hindered aromatic amine, or derivative thereof.

In some embodiments, the radical scavenging additive is a hindered amine compound. The hindered amine compound can react with oxygen or reactive oxygen species to form a stable and sterically hindered aminoxyl (—NO⁻) radical which can preferentially react with other radical species instead of the non-radical components of the photoresist. In some embodiments, the radical scavenger additive is TEMPO ((2,2,6,6-tetramethylpiperidin-1-yl)oxyl) or TEMPOL ((4-Hydroxy-2,2,6,6-Tetramethylpiperidin-1-yl)oxyl). In some embodiments, the radical scavenger additive is 2-phenyl-4,4,5,5-tetramethylimidazoline-1-oxyl 3-oxide (PTIO).

In additional or alternative embodiments, the precursor solutions can further comprise a photoacid generator or related UV absorbing quenching compounds. Photoacid generators (PAGs) have been found to be effective for absorbing scattered electrons or photons to reduce noise from irradiation. These additives have been found to be particularly helpful in positive tone patterning. This is described in published U.S. patent application 2024/0085785 to Kasahara et al. (hereinafter the '785 application), entitled “Additives for Metal Oxide Photoresists, Positive Tone Development With Additives, and Double Bake Double Develop Processing,” incorporated herein by reference. The photoacid generators generally comprise onium salts, and the inclusion of onium salts can provide iodide ions or not. Onium compounds have a cation or zwitterion formed from a group 15 to group 17 core atom, such as iodonium, sulfonium, ammonium, phosphonium, and the like, which have functional groups for UV absorption. In principle, the onium ions for the PAGs can be the ammonium ions used to introduce all or the bulk of the iodide ions, but the iodide ion concentrations and the PAG concentrations are generally selected independently, so it is desirable to include the ammonium iodide for introduction of the desired amount of iodide ions and the PAG concentration separately, with potential adjustment of the ammonium iodide if additional iodide in introduced with the PAG.

While PAGs can generally absorb at UV and EUV wavelengths, their presence in an already high EUV absorbance Sn-based matrix implies that the presence of PAGs does not significantly attenuate EUV light available to the organotin patterning compositions. PAGs can also generate acidic protons in response to secondary electrons generated from EUV absorption. Evidence in the '785 application suggests that PAGs facilitate removal of organic species from irradiated patterning composition, which are presumed related to the cleaved R-groups freed from their bond to the tin.

PAGs known in the art are generally onium compounds, which have a cation formed from a group 15 to group 17 core atom, such as iodonium, sulfonium, ammonium, phosphonium, and the like. Particularly effective PAGs have aromatic substituents and derivatives thereof, such as aromatic onium ions. PAGs traditionally has complex aromatic anions that are conjugate bases of strong acids, as described in the '785 application, which also provide good solubility. As noted in the '785 application, the anions can be substituted with conjugate bases of weak acids, in which the resulting compound does not generate an acid, but still functions as a beneficial quencher. In the present context, either set of anions from the '785 application can be used, and the following additives in Table 1 were exemplified there. Alternatively, the anion can be I⁻ if the resulting salt is sufficiently soluble, such as triphenylsulfonium iodide, triphenylphosphonium iodide, triphenylammonium iodide, mixtures thereof, or the like.

TABLE 1

| Additive | | |
|---|---|---|
| Reference | | |
| Name | Additive Formula | MW (g/mol) |
| A1 | 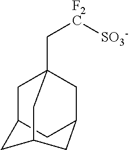 | 542.7 |
| | 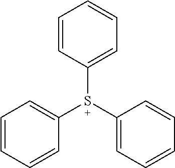 | |
| A2 | 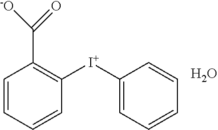 | 342.1 |
| A3 | 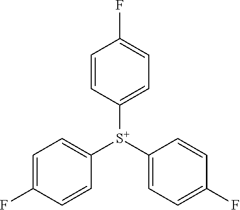 [SMILES: Fc1ccc([S+](c2ccc(F)cc2)c2ccc(F)cc2)cc1] | 522.5 |
| | 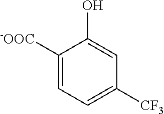 | |
| A4 | 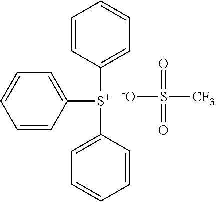 | 412.5 |

With respect to the PAG additives, these can be specified as a mole ratio relative to the tin or as a molarity. The additive can be in the solution at a mole ratio to tin of 0.002 to 0.5, in further embodiment from about 0.0035 to about 0.45, in additional embodiments from about 0.005 to about 0.4 and in some embodiments from about 0.0075 to about 0.3 moles additive per mole of tin. Similarly, the precursor solution can comprise additive at a concentration from about 0.000025M to about 0.4M in further embodiments form about 0.00005M to about 0.35M and in additional embodiments from about 0.0001M to about 0.2M. A person of ordinary skill in the art will recognize that additional concentration ranges and values within the explicit ranges above are contemplated and are within the present disclosure.

In some embodiments, the aromatic onium ion is an iodide salt, such as triphenylsulfonium iodide, which provides both the benefits of the aromatic onium cation and additional iodide ions for enhanced EUV absorption. The total iodide content in the precursor solution may be adjusted by selecting the appropriate amounts of ammonium-based iodide and onium iodide compounds. In some embodiments, the precursor solution comprises both an ammonium-based iodide compound and an aromatic onium iodide compound, providing iodide from multiple sources. In some embodiments the molar ratio of ammonium-based iodide to aromatic onium iodide may range from about 10:1 to about 1:10, in further embodiments from about 5:1 to about 1:5, and in additional embodiments from about 2:1 to about 1:2. In some embodiments the molar ratio of ammonium-based iodide to aromatic onium iodide is about 1:1. A person of ordinary skill in the art will recognize that additional molar ratios and values within the explicit ranges above are contemplated and are within the present disclosure.

The radical scavenger and/or PAG additives and the ammonium-based iodide compound may be added to the precursor solution in any order. In some embodiments, the additive(s) are added first, followed by the ammonium-based iodide. In other embodiments, the ammonium-based iodide is added first, followed by the additives. In further embodiments, the additives are added simultaneously with the ammonium-based iodide compound. The presence of both additives in the precursor solution can provide synergistic benefits, for example with the radical scavenger reducing undesirable radical-induced reactions in unexposed regions, the PAG reducing photon shot noise, and the iodide enhances EUV absorption and reduces thermal decomposition temperatures. The combined use of radical scavengers and/or PAG additives with ammonium-based iodide additives can enable lower patterning doses while maintaining or improving pattern quality compared to solutions containing only one additive or no additives.

A radiation patternable coating can be formed through deposition and subsequent processing of the iodide enhanced organotin compositions onto a selected substrate. Deposition of radiation patternable coatings can be achieved through various means known by those of ordinary skill in the art. Particularly useful deposition techniques employing organotin materials have been described by Meyers et. al in U.S. Pat. No. 10,228,618 entitled “Organotin oxide hydroxide patterning compositions, precursors, and patterning”, and by Wu et. al in PCT Patent App No. PCT/US2019/031618 entitled “Methods for Making EUV Patternable Hard Masks”, both of which are incorporated herein by reference

In one embodiment, the photoresist precursors with iodide supplying organotin compositions can be used to form radiation-patternable organotin oxo hydroxo materials incorporating the iodine/iodide via solution deposition techniques, such as spin coating. In a typical spin coating process, a volume of a photoresist solution is introduced onto the surface of a substrate, and the substrate is rotated at high speeds to drive rapid evaporation and hydrolysis processes, generally with atmospheric water, to enable the formation of a radiation patternable coating. In some embodiments, the substrate can be spun at rates (i.e., spin speeds) from about 500 rpm to about 10,000 rpm, in further embodiments from about 1000 rpm to about 7500 rpm, and in additional embodiments from about 2000 rpm to about 6000 rpm. The spin speed can be adjusted to obtain a desired coating thickness for a given precursor solution and for a given substrate size. The spin coating can be performed from about 5 seconds to about 5 minutes and in further embodiments from about 15 seconds to about 2 minutes. An initial low speed spin, e.g., at 50 rpm to 250 rpm, can be used to perform an initial bulk spreading of the composition across the substrate. A back side rinse, edge bead removal step, or the like can be performed with water or other suitable solvent to remove any edge bead. See, for example, U.S. Pat. No. 10,627,719 to Waller et al., entitled “Methods of Reducing Metal Residue in Edge Bead Region From Metal-Containing Resists,” incorporated herein by reference. A person or ordinary skill in the art will recognize that additional ranges of spin coating parameters within the explicit ranges above are contemplated and are within the present disclosure.

In another embodiment, the photoresist precursors with organotin compositions having iodo ligands can be used to form radiation-patternable organotin oxo hydroxo materials incorporating the iodine atoms via vapor deposition techniques, such as chemical vapor deposition (CVD), atomic layer deposition (ALD), and the like. The organotin precursors with iodo ligands have sufficient vapor pressure for vapor deposition. ALD can be used to form precursor blends in the resulting films, with alternating ALD steps with particular precursors to achieve the desired portion in the final film. In principle, the desired precursor blends can be deposited in one CVD step, but due to different vapor pressures and generally different deposition efficiencies, such an approach involves precise process controls. Vapor deposition methods have previously been employed to deposit inorganic metal oxide and nitride films with metal alkylamide, alkoxide, and halide precursors. Similarly, vapor deposition methods have been used to deposit radiation-patternable organotin oxide hydroxide films by reacting an organotin precursor, RSnL₃, with water, as described in the '505 patent. Vapor deposition is generally performed by reacting one or more metal-containing precursors with small molecule gas-phase reagents such as H₂O, H₂O₂, O₃, O₂, or CH₃OH, which serve as O and H sources for production of oxides and oxide hydroxides. If desired, vapor deposition approaches can also be performed in which the precursor compositions with ligands having hydrolysable bonds to Sn are deposited from the vapor phase and the bonds subsequently hydrolysed after coating formation, but for vapor phase processing, hydrolysis/oxidation during the deposition generally may be more efficient. Some advantages of vapor deposition may include, for example, fine control of deposition reaction conditions, reduced resist film defect density, improved thickness and compositional uniformity, as well as conformal and side-wall coating of substrate topography.

The hydrolysis of the hydrolysable ligands can take place during deposition and/or in the resulting film, such as during a post application bake step. These general concepts are believed to apply for both the solution deposition approach and the vapor deposition approach. The iodide ligands are observed to be partially hydrolysable, and similar results regarding maintenance or removal of iodine follow whether the iodine is introduced as an iodo/iodide ligand to tin or as an ammonium iodide additive. While not wanting to be limited by theory, the hydrolysis involving the iodide could be taking place through the formation of HI, which is a gas, and the generation of OH, which may bond to tin as a ligand. If ammonium (NH₄⁺) is deprotonated, ammonia is formed that can evaporate from the film. Organo-ammonium ions with hydrogens can similarly deprotonate, which can form volatile neutral compounds. As noted below, patternable organo tin films formed with NH₄I additives are found to be free of nitrogen prior to irradiation. It is also observed that a moderate portion of iodine remains in the films indicating that not all of the iodide ions are removed from the film through the formation of volatile species and/or through subsequent thermal processing such as a post application bake (PAB). Thus, iodine remains to influence the patterning process. The remaining iodine can be characterized by way of the percent of initial iodine remaining in the patternable film or as a mole percent relative to the tin. In general, it is desirable for the processing conditions to provide a retention of iodine in the processed film, measured as the molar ratio of iodine to Sn in the processed film relative to the initial molar ratio of iodine to Sn in the precursor composition, of at least 5%. In some embodiments, the retention is at least 10%, at least 25% in other embodiments, and in further embodiments at least 50%. It may be desirable to retain most or all of the initial iodine, although compositions can be adjusted to compensate for retention achieved. The retention can be influenced by processing conditions, and factors that may influence iodine retention include, but may not be not limited to, iodine source in precursor solution, precursor solution water concentration, ambient atmosphere water concentration, solvent identity, post application bake (PAB) temperature, and PAB duration. Based on the percent retention and the initial molar ratio of iodine to tin in the precursor composition, such as precursors with iodide ligands or ammonium based iodide, the resulting mole percent of iodide in the coating is established. Generally, the mole percent iodine relative to tin is at least about 0.05 mole %, in further embodiments at least about 0.1 mole % and in other embodiments at least about 0.25 mole %. A person of ordinary skill in the art will realize that additional retention values above or between the explicit lower limits above are contemplated and are within the scope of the disclosure.

The organotin iodo compounds described herein having the formula RSnL₃₋Iₓ, where, x=1, 2, or 3, and L is a ligand that forms a hydrolysable bond with the Sn, such as a dialkylamide (—NR′₂), an alkoxide (—OR′), an acetylide (—CCR′), a carboxylate (—COOR′) can be used to directly deposit via vapor phase hydrolysis the corresponding iodine-enhanced alkyl tin oxide hydroxide coating, which can then be appropriately patterned.

No matter the deposition method employed, the photoresist film comprising the iodine-enhanced alkyl tin oxide hydroxide, RSnO_{3/2-x/2-z/2}(OH)ₓI_{z}, and/or RSnO_{3/2-x/2-z/2}(OH)ₓ·HI, network composition can be formed on a suitable substrate. The coatings comprise Sn atoms connected through Sn—O—Sn and Sn—OH bonds to form an extended network. The organic ligands (R groups) remain bonded to the tin through Sn—C bonds, which are generally not hydrolyzable under the processing conditions used. The iodine atoms are incorporated into the network, potentially through Sn—I bonds, hydrogen bonding with hydroxyl groups, or other interactions. The exact nature of the iodine incorporation may vary depending on the processing conditions and may include multiple bonding modes. As noted above, some of the iodine in the precursors can get removed during processing, potentially by hydrolysis. The amount of iodine within the film can be dependent upon the amount of iodine within the precursor as well as by the processing. In some embodiments, z values for RSnO_{3/2-x/2-z/2}(OH)ₓI_{z}, can be from about 0.01 to about 2.0, in some embodiments from about 0.01 to about 1.5, and in some embodiments from about 0.01 to about 1.0. A person of ordinary skill in the art will recognize that additional values for z within the explicit ranges above are contemplated and are within the present disclosure.

The substrate generally presents a surface onto which the coating material can be deposited, and the substrate may comprise a plurality of layers in which the surface relates to an upper most layer. The substrate surface can be treated to prepare the surface for adhesion of the coating material. Prior to preparation of the surface, the surface can be cleaned and/or smoothed as appropriate. Suitable substrate surfaces can comprise any reasonable material. Some substrates of interest include, for example, silicon wafers, silica substrates, other inorganic materials, polymer substrates, such as organic polymers, composites thereof and combinations thereof across a surface and/or in layers of the substrate. In some embodiments, the substrate can comprise a patterned structure such as described by Stowers et al. in U.S. Pat. No. 10,649,328, entitled “Pre-Patterned Lithography Templates, Process Based on Radiation Patterning Using The Templates And Processes To Form The Templates”, incorporated herein by reference.

The coating material following deposition may generally form a metal oxo-hydroxo-iodo network based on the binding oxo-hydroxo-iodo network to the metals in which the metals also have some organo ligands, or a molecular solid comprised of polynuclear metal oxo/hydroxo/iodo species with organo ligands. While heating may not be needed for successful application of the process, it can be desirable to heat the coated substrate in a so-called post-application bake (PAB) process to speed the processing and/or to increase the reproducibility of the process and/or to facilitate vaporization of the hydrolysis by products, such as amines and/or alcohols. In some embodiments, the coating material can be heated at temperatures from about 45° C. to about 220° C., in some embodiments from about 50° C. to about 190° C., and in further embodiments from about 55° C. to about 175° C. The heating for solvent removal can generally be performed for at least about 0.1 minute, in further embodiments from about 0.5 minutes to about 30 minutes and in additional embodiments from about 0.75 minutes to about 10 minutes. In some embodiments, the coating material can be heated during the vapor deposition process. In embodiments wherein a vapor deposition process is used to form the photoresist film, the substrate can be heated at a temperature of about 45° C. to about 220° C., in some embodiments from about 50° C. to about 190° C., and in further embodiments from about 55° C. to about 175° C. A person of ordinary skill in the art will recognize that additional ranges of heating temperature and times within the explicit ranges above are contemplated and are within the present disclosure.

Coating thickness for radiation patternable coatings prepared by solution deposition can generally be controlled through appropriate control of precursor solutions Sn concentration and rotation speed of the wafer. For films prepared by vapor deposition techniques, film thickness can generally be controlled through appropriate selection of reaction time or cycles of the process. The thickness of the radiation patternable coating can depend on the desired process. For use in single-patterning EUV lithography, coating thicknesses are generally chosen to yield patterns with low defectivity and reproducibility of the patterning. In some embodiments, suitable coating thickness can from between 1 nm and 100 nm, in further embodiments from about 2 nm to 50 nm, and in further embodiments from about 3 nm to 25 nm. Those of ordinary skill in the art will understand that additional ranges of coating thickness are contemplated and are within the present disclosure.

Radiation generally can be directed to the coated substrate through a mask, or a radiation beam can be controllably scanned across the substrate. In general, the radiation can comprise electromagnetic radiation, an electron-beam, or other suitable radiation. In general, deep ultraviolet (DUV) radiation having a wavelength of about 193 nm and extreme ultraviolet (EUV) radiation having a wavelength of about 13.5 nm can be particularly desirable for the formation of fine patterns for the fabrication of semiconductor devices, and both technologies are currently used in the lithographic patterning of high-performance semiconductor devices. EUV radiation can generally be generated from Xe or Sn plasma and used in state of the art lithography platforms, such as EUV scanner tools from ASML (Veldhoven, NL). While DUV and EUV are used in state-of-the-art lithographic processing, other forms of radiation can also be used to generate patterns in the photoresist, such as electron beams, ion beams, ultraviolet light, and x-rays. The amount of electromagnetic radiation can be characterized by a fluence or dose which is obtained by the integrated radiative flux over the exposure time. For embodiments utilizing EUV radiation, suitable can be from about 1 mJ/cm² to about 150 mJ/cm², in other embodiments from about 2 mJ/cm² to about 100 mJ/cm² and in further embodiments from about 3 mJ/cm² to about 50 mJ/cm². A person of ordinary skill in the art will realize that additional ranges of radiation fluences within the explicit ranges listed above are contemplated and are within the scope of the present disclosure.

In some embodiments, a post-exposure bake (PEB) process can be performed to enhance the contrast of material properties between the irradiated regions that have depleted Sn—C bonds and/or have condensed coating material with increased metal oxide character and the unirradiated, coating material with substantially intact Sn—C bonds. The post-irradiation heat treatment can be performed at temperatures from about 45° C. to about 225° C., in additional embodiments from about 50° C. to about 190° C. and in further embodiments from about 60° C. to about 175° C. The post exposure heating can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of post-irradiation heating temperature and times within the explicit ranges above are contemplated and are within the present disclosure. This high contrast in material properties further facilitates the formation of high-resolution lines with smooth edges in the pattern following development as described in the following section.

Following exposure and any subsequent thermal processing or rest steps, the coated substrate can be developed to extract the latent image pattern as a physical pattern. In a development process, regions of the organometallic coating can be selectively removed while other regions remain substantially intact. In some embodiments, the development process is a negative tone development process wherein the unexposed regions are selectively removed by a developer composition while the exposed regions remain substantially to form a negative pattern. In some embodiments, the development process is a positive tone development process wherein the exposed regions are selectively removed by a developer composition while the unexposed regions remain substantially intact to form a positive pattern.

For the negative tone imaging, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity and potential chemical interactions with other process material. In particular, suitable developers include, for example, alcohols (e.g., 4-methyl-2-pentanol, 1-butanol, isopropanol, 1-propanol, methanol), ethyl lactate, ethers (e.g., tetrahydrofuran, dioxane, anisole), esters (e.g., PGMEA), ketones (e.g., pentanone, hexanone, 2-heptanone, octanone) and the like. The development can be performed for about 5 seconds to about minutes, in further embodiments from about 8 seconds to about 15 minutes and in additional embodiments from about 10 seconds to about 10 minutes. A person of ordinary skill in the art will recognize that additional ranges within the explicit ranges above are contemplated and are within the present disclosure. In addition to the primary developer composition, the developer can comprise additional compositions to facilitate the development process. Suitable additives may include, for example, viscosity modifiers, solubilization aids, or other processing aides. If the optional additives are present, the developer can comprise no more than about 10 weight percent additive and in further embodiments no more than about 5 weight percent additive. A person of ordinary skill in the art will recognize that additional ranges of additive concentrations within the explicit ranges above are contemplated and are within the present disclosure. Additional useful developers have been described by Cardineau et al. in U.S. Pat. No. 12,416,861, entitled “Organometallic photoresist developer compositions and processing methods”, incorporated herein by reference.

For positive tone development, suitable developers can be aqueous bases. In some embodiments, aqueous bases can be used to obtain sharp physical images. To reduce contamination from the developer, it can be desirable to use a developer that does not have metal atoms. Thus, quaternary ammonium hydroxide compositions, such as tetraethylammonium hydroxide, tetrapropylammonium hydroxide, tetrabutylammonium hydroxide or combinations thereof, are desirable positive tone developers. In general, the quaternary ammonium hydroxides of particular interest can be represented with the formula R₄NOH, where R=independently, an alkyl group, such as a methyl group, an ethyl group, a propyl group, a butyl group, or combinations thereof. The coating materials described herein generally can be developed with the same developer commonly used presently for polymer resists, specifically aqueous tetramethyl ammonium hydroxide (TMAH). Commercial TMAH (aq) is available at 2.38 weight percent. Furthermore, mixed quaternary tetraalkyl-ammonium hydroxides can be used. In general, the developer can comprise from about 0.5 to about 30 weight percent, in further embodiments from about 1 to about 25 weight percent and in other embodiments from about 1.25 to about 20 weight percent tetra-alkylammonium hydroxide or similar quaternary ammonium hydroxides. A person of ordinary skill in the art will recognize that additional ranges of developer concentrations within the explicit ranges above are contemplated and are within the present disclosure. For a positive tone developer, it can be desirable to dissolve material densified and/or chemically altered from a relatively high radiation dose, assuming that the non-irradiated material is not significantly removed.

It has also been discovered that solventless development, also referred to as dry development, can be employed with organotin materials for negative tone patterning wherein selective removal of the non-irradiated regions of the photoresist is achieved by exposing the material to an appropriate plasma or appropriate flowing gas. Dry development of organotin resists has been described in PCT Publication No. 2020/132281A1 by Volosskiy et al., entitled “Dry Development of Resists”, and in published U.S. Patent Application No. 2023/0100995 to Cardineau et al., entitled “High Resolution Latent Image Processing and Thermal Development”, both of which are incorporated herein by reference. In such dry development processes, development can be achieved by exposing the irradiated substrate to a plasma or a thermal process while flowing a gas comprising a small molecule reactant (reactive gas) that facilitates removal of non-irradiated regions. In some embodiments, the developer can be HBr or HBr plasma. In other embodiments, the reactive developer gas can be a compound QₓZ_{y} or where Q is B, Al, Si, C, S, or SO with x>0 and Z is Cl, H, Br, or F with y>0. In further embodiments, the reactive developer gas can be an amine, a silyl halide, an alcohol, an amide, a sulfonic acid, a carboxylic acid, a thiol, tin halide, germanium halide, and mixtures thereof. The reactive gas species can be introduced in a gaseous form or activated into a plasma state to enhance reactivity. Following development, a rinse step can be conducted using water, a positive tone developer solution or the like, if desired to further remove undesired material from the pattern, and such methods have been described in U.S. Pat. No. 11,480,874 to Kocsis et al., entitled “Patterned Organometallic Photoresists and Methods of Patterning,” incorporated herein by reference.

Solventless development can be performed at various process conditions and the process conditions can be selected to achieve the desired development for certain developer species and organometallic coatings. The temperature of the developer gas or etch chamber can influence the efficacy of the solventless development, as can the duration of the development, and the pressure of the etch chamber during development. In some embodiments, the solventless development can be performed at a temperature from about 10° C. to about 100° C., from about 20° C. to about 80° C., or from about 30° C. to about 60° C. In other embodiments, the solventless development can be performed at a temperature from about 100° C. to about 250° C., from about 120° C. to about 230° C., or from about 150° C. to about 200° C. In some embodiments, the solventless development process can be performed for about 10 seconds, about 20 seconds, or about 40 seconds. In other embodiments, the solventless development process can be performed for more than about 3 seconds and less than about 5 minutes, from about 10 seconds to about 2 minutes in further embodiments, and from about 20 seconds to about 60 seconds in yet further embodiments. In some embodiments, the solventless development process can be performed at reduced pressures in other embodiments the solventless development process can be performed at near atmospheric pressures, and in other embodiments the solvent development process can be performed at higher than atmospheric pressures. In other embodiments pressure can be from about 0.1 mTorr (mT) to about 800 mT, in other embodiments the pressure can be from about 1 mT to about 500 mT, and from about 10 mTorr to about 300 mT in further embodiments. In embodiments wherein the solventless development process is conducted at pressures near or above atmospheric pressure, the solventless development process can be performed at pressures from about 100 Torr to about 1000 Torr, from about 100 Torr to about 800 Torr in further embodiments, and from about 200 Torr to about 800 Torr in other embodiments. A person of ordinary skill in the art will realize that additional values of temperatures, durations, and pressures within the explicitly recited ranges above are contemplated and part of the present disclosure.

After completion of the development step and any optional rinses, the coating materials can be heat treated to further condense the material and to further dehydrate, densify, or remove residual developer from the material. This heat treatment, hard bake, can be particularly desirable for embodiments in which the oxide coating material is incorporated into the ultimate device, although it may be desirable to perform the heat treatment for some embodiments in which the coating material is used as a resist and ultimately removed if the stabilization of the coating material is desirable to facilitate further patterning. In particular, the hard bake of the patterned coating material can be performed under conditions in which the patterned coating material exhibits desired levels of etch selectivity. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiment for about 2 minutes to about 1 hour, in further embodiments from about 2.5 minutes to about 25 minutes. The heating may be performed in air, vacuum, or an inert gas ambient, such as Ar or N₂. A person of ordinary skill in the art will recognize that additional ranges of temperatures and time for the heat treatment within the explicit ranges above are contemplated and are within the present disclosure. Likewise, non-thermal treatments, including blanket UV exposure, or exposure to an oxidizing plasma such as O₂ may also be employed for similar purposes.

While the organotin based patterning compositions are effective to achieve highly desirable results with negative tone or positive tone patterning, the results obtained with the iodine-based additives provide particularly notable performance for positive tone patterning. Positive tone patterning is generally used to form challenging structures, such as a pattern of holes or pillars. As exemplified herein, a pattern of holes with low variability can be achieved with dose of less than 90 mJ/cm² and a numerical aperture of 0.33. Specifically, at a dose of less than 90 mJ/cm², a hole pattern with a hole diameter less than 25 nm, the 30 LCDU of less than about 3.25 nm, in further embodiments less than about 3.0 nm and in additional embodiments from about 2.75 nm to about 2.95 nm can be obtained. A person of ordinary skill in the art will recognize that additional ranges of 3σ LCDU within the explicit ranges above are contemplated and are within the present disclosure.

### Examples

Example 1: Synthesis of iPrSnI₃

Isopropyl tin triiodide was synthesized from isopropyl triphenylstannane (Ph₃SniPr) as summarized in reaction scheme below.

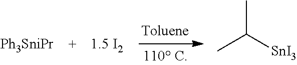

Isopropyl triphenylstannane (Ph₃SniPr) was synthesized according to methods described in J. Chem. Soc., Dalton Trans., 1990, 2643-2651. Isopropylmagnesium chloride was added slowly to a solution of triphenyltin chloride in diethyl ether at −20° C., and the reaction mixture was then warmed to room temperature and the solvent was removed via vacuum. The reaction product was then taken up in pentane and filtered to obtain Ph₃SniPr.

Isopropyl triphenylstannane (Ph₃SniPr) (25 mmol) was mixed with iodine (75 mmol) slowly in toluene and the reaction mixture was heated at 110° C. for 24 hours. Multiple distillation steps were then performed to purify and isolate the target compound. Distillation was first conducted at 70° C. followed by filtration to remove solids. Then, another distillation was performed at 105° C. to obtain the crude compound which was then purified via trap-to-trap distillation at 80° C. to afford the target compound (iPrSnI₃) in 73% yield. ¹¹⁹Sn NMR (400 MHz, neat) −δ132.96 ppm, 1H NMR (400 MHz, d⁸-toluene), (δ 0.70, 2CH₃), (δ 1.76, CH).

### Example 2: Preparation of Organotin Iodo Precursor Blends

Appropriate masses of iPrSnI₃ and iPrSn(OtAm)₃ were mixed together in different molar ratios to prepare precursor blends according to Table 2.

TABLE 2

| Precursor Blend | Mol. % iPrSnI₃ | Mol. % iPrSn(OtAm)₃ |
|---|---|---|
| SA1 | 50 | 50 |
| SA2 | 25 | 75 |
| SA3 | 10 | 90 |
| CS-1 | 100 | 0 |
| CS-2 | 0 | 100 |

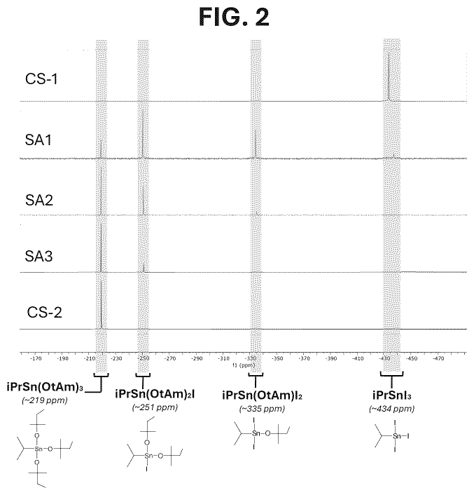

Control samples of the neat unblended compounds iPrSnI₃ and iPrSn(OtAm)₃, CS-1 and CS-2, respectively, were also prepared. Following mixing, the blended precursors were sealed and left to equilibrate for approximately 3 days. ¹¹⁹Sn NMR spectra were then collected for each sample to determine the relative distribution of organotin iodo-alkoxo species. As shown in FIG. 2, the ¹¹⁹Sn NMR spectra indicate that the blends each have a different distribution of distinct iPrSn(OtAm)₃₋ₓIₓ species. Blend SA1, prepared from an initial 50%/50% molar mixture (1:1 molar ratio) of CS-1 and CS-2, shows the presence of x=0, 1, 2, and 3 species corresponding to iPrSn(OtAm)₃, iPrSn(OtAm)₂I, iPrSn(OtAm)I₂, and iPrSnI₃, respectively, with the x=1 and x=2 species as the predominant species. Blend SA2, prepared from an initial a 25%/75% molar mixture (1:3 molar ratio) of CS-1 and CS-2, shows the presence of x=0, 1, and 2 species and the absence of the triiodo CS-1 compound. Blend SA3, prepared from an initial 10%/90% molar mixture (1:9 molar ratio) of CS-1 and CS-2, shows the presence of x=0 and 1 species. For comparison, the ¹¹⁹Sn NMR spectra for CS-1 and CS-2 show only single peaks corresponding to their respective compounds. The ¹¹⁹Sn NMR spectra indicate that the distribution of species in the iodo-alkoxo blends is dependent on the initial concentrations of the precursors and that redistribution of the iodo and alkoxo ligands occurs to result in a distribution of mixed iodo-alkoxo species. Higher initial concentrations of iPrSnI₃ lead to distributions comprising iodo-rich species, such as iPrSn(OtAm)I₂. Integration of the peak areas for each species in each sample were collected and the weighted averages for each species were calculated, allowing the general formula for each precursor blend composition to be determined as shown in Table 3.

TABLE 3

| Precursor Blend | General Compositional Formula |
|---|---|
| SA1 | iPrSn(OtAm)_{1.53}I_{1.47} |
| SA2 | iPrSn(OtAm)_{2.27}I_{0.73} |
| SA3 | iPrSn(OtAm)_{2.66}I_{0.34} |

Example 3: Preparation of tBuSn(OtAm)₃₋ₓIₓ Precursors Synthesis and NMR Analysis

SnI₂ (5.03 g, 13.5 mmol) was suspended in toluene (15 mL) and tBuSn(OtAm)₃ (5.88 g, 13.5 mmol) was added at RT. After stirring for 72 hours, the color changes from bright orange to light yellow. The contents were filtered to remove an insoluble yellow percipitate, determined using 1H NMR and ¹¹⁹Sn NMR to be primarily ISn(OtAm), and toluene was removed in vacuo. The product was extracted with pentane and filtered. Pentane was removed in vacuo to obtain the tBuSn(OtAm)₃₋ₓIₓ product sample as yellow liquid (4.62 g, 72%). ¹¹⁹Sn NMR (400 MHz, neat) was conducted on the product to determine the distribution of individual tBuSn(OtAm)₃₋ₓIₓ species present, and it was determined that the product comprised approximately a 1:2:1 molar distribution of tBuSn(OtAm)₃:tBuSn(OtAm)₂I:tBuSn(OtAm)I₂ based on integrated peak areas (ipa) of the peaks corresponding to tBuSn(OtAm)₃ (δ −240.8 ppm, ipa=26.38), tBuSn(OtAm)₂I (δ −268.76 ppm, ipa=52.6), and tBuSn(OtAm)I₂ (δ −324.22 ppm, ipa=20.04). Accordingly, the composition of the precursor blend can therefore be represented by the overall formula tBuSn(OtAm)_{2.06}I_{0.94}.

### Example 4: Thermal Decomposition of Blended Photoresists

A series of photoresist solutions were prepared by combining appropriate amounts of the tert-butyltin iodo alkoxide composition in previous Example 3(TBI) with tert-butyltin tris (tert-amyl alkoxide) (CS-3) in a solvent blend of 38 wt. % 1-pentanol/62 wt. % 1-propanol having approximately 300 ppm H₂O by weight to afford the photoresist solutions having a total [Sn] concentration of 0.05 M and having the molar amounts of TBI and CS-3 as summarized in Table 4.

TABLE 4

| Sample Name | Mol. % TBI | Mol. % CS-3 |
|---|---|---|
| TA1 | 100 | 0 |
| TA2 | 50 | 50 |
| TA3 | 25 | 75 |
| TA4 | 10 | 90 |

The solutions were then used to prepare photoresist films via spin coating onto 4 in. diameter undoped Si wafers. The coated wafers were then cleaved into 1-inch chips and were subjected to baking on a hotplate at 40° C., 55° C., 70° C., 85° C., 100° C., 120° C., 140° C., or 160° C. for 2 minutes. An additional chip was reserved for analysis that received no hotplate bake. The film thickness of the unbaked chip samples were collected via ellipsometry to give film thicknesses of 22.6 nm, 24.4 nm, 22.8 nm, 22.1 nm for films prepared from Samples TA1, TA2, TA3, and TA4, respectively.

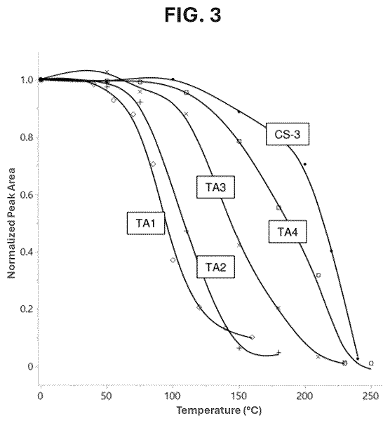

The films were then analyzed via FTIR to determine the alkyl content in each film as a function of bake temperature. The peak areas corresponding to the C—H stretching region between 3010 cm⁻¹ and 2783 cm⁻¹ were measured for each sample and were then normalized to the peak areas obtained for the unbaked samples (i.e., the C—H peak areas were normalized to the initial C—H peak areas for non-baked samples). The normalized peak areas for each sample were then plotted versus bake temperature to result in the plot shown in FIG. 3.

As seen in FIG. 3, the normalized C—H absorbance peak areas for samples comprising greater amounts of the organotin iodo-alkoxo composition TBI more rapidly diminish with temperature than for samples having lesser amounts of TBI. The presence of iodine within the films significantly affects the thermal stability of the C—Sn bonds in the films, allowing for greater cleavage of the C—Sn bonds are lower temperatures with increasing iodine content. A film sample prepared from a non-iodo composition, tBuSn(OtAm)₃ (CS-3), was also measured and plotted in Figure X for comparison. In all cases, the loss of peak area associated with the C—H stretch of the alkyl groups (i.e., tert-butyl) bound to the Sn atoms is greater at all temperatures in comparison to the non-iodo composition CS-3. These results indicate that cleavage of the Sn—C bonds in organotin iodo-oxo-hydroxo films via radiolysis and/or thermolysis can be achieved at lower energies than for non-iodo films, thereby offering a path to lower patterning doses.

### Example 5: Thermolysis of Ammonium Iodide Enhanced Organotin Photoresist Compositions

Organotin precursor solutions were prepared by combining appropriate amounts of methyltin tris (tert-butoxide) and tert-butyltin tris (pentan-3-yloxide) to afford a 20 mol. %/80 mol. %, respectively, ratio in a solvent blend of 38 wt. % 1-propanol/62 wt. % 1-pentanol to yield a stock solution (SS) having a total [Sn] concentration of 0.05M and absent of ammonium iodide additive. Appropriate amounts of ammonium iodide were then adding to aliquots of stock solution SS and mixed with stirring to prepare organotin ammonium iodide solutions SI1, SI2, and SI3 having 0.005 M [NH₄I] (10 mol. % relative to Sn), 0.01M [NH₄I] (20 mol. % relative to Sn), or 0.025M [NH₄I] (50 mol. % relative to Sn), respectively.

The solutions were then used to prepare photoresist films via spin coating onto 4 in. diameter undoped Si wafers. The coated wafers were then cleaved into 1-inch chips and were subjected to baking on a hotplate at 50° C., 100° C., 150° C., 180° C., 200° C., 220° C., 240° C., or 265° C. for 2 minutes. An additional chip was reserved for analysis that received no hotplate bake. The film thickness of the unbaked chip samples was collected via ellipsometry to give film thicknesses for films prepared from Samples SI1, SI2, SI3, and SS of 20.9 nm, 21.7 nm, 24.1 nm, and 21.0 nm, respectively.

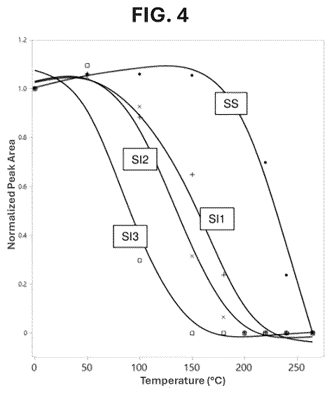

The films were then analyzed via FTIR to determine the alkyl content in each film as a function of bake temperature. The peak areas corresponding to the C—H stretching region between 3050 cm⁻¹ and 2750 cm⁻¹ were measured for each sample and were then normalized to the peak areas obtained for the unbaked samples (i.e., the C—H peak areas were normalized to the initial C—H peak areas for non-baked samples). The normalized peak areas for each sample were then plotted versus bake temperature to produce the plot shown in FIG. 4.

The film samples prepared from organotin compositions with ammonium iodide show a decrease in thermal decomposition temperature such that the peak areas associated with the alkyl groups lose intensity at lower temperatures than for films prepared from the SS composition without ammonium iodide. Furthermore, as the amount of ammonium iodide is increased a further decrease in thermal decomposition is observed. The films SI1, SI2, and SI3 prepared from ammonium iodide containing samples show a relationship between ammonium iodide concentration and thermal decomposition temperature wherein increasing levels of ammonium iodide correlate with decreasing thermal decomposition temperatures. SI3, prepared from a sample containing 0.025M ammonium iodide, shows significantly more loss of C—H peak area at temperatures of 100° C. and above than the film prepared from solutions with less ammonium iodide. As shown in FIG. 4, the trend of decomposition temperatures follows with SS>SI1>SI2>SI3.

Similar to the behavior is seen as in Example 3 where increasing iodine content leads to reduced thermal decomposition temperature. The presence of iodine within the organotin oxide hydroxide material leads to lower decomposition temperatures. These results suggest that iodo ligands can be a useful addition to organotin photoresists to lower processing temperatures needed to render the material insoluble, thereby providing a path towards lower patterning doses.

Example 6: Incorporation of Iodine into Organotin Films Deposited from Ammonium Iodide Enhanced Precursor Solutions.

Two ammonium iodide enhanced photoresist precursor solutions were prepared by combining a solvent, an organotin composition comprising a blend of two compounds from those listed in Table 5, and an ammonium iodide additive, according to Table 6. Each precursor solution was deposited on a 300 mm Si wafer via spin coating to form coatings having a thickness of about 19.5 nm, as determined by ellipsometry.

TABLE 5

| Compound | Structure |
|---|---|
| P1 | 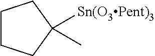 |
| P2 | 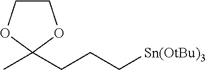 |
| P3 | 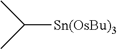 |
| P4 | 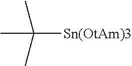 |

TABLE 6

| | | Organotin | | | |
|---|---|---|---|---|---|
| | Solvent | Composition | | | |
| Precursor | (Solvent, | (Compound, | [Sn] | NH₄I:Sn | [H₂O] |
| Solution | Weight %) | Molar %) | (M) | (Molar) | (ppm) |
| UA1 | 1-pentanol, 62% | P1, 80% | 0.048 | 0.1:1 | 300 |
| | 1-propanol, 38% | P2, 20% | | | |
| UA2 | 1-pentanol, 62% | P3, 20% | 0.050 | 0.1:1 | 300 |
| | 1-propanol, 38% | P4, 80% | | | |

The coated wafers were subjected to a post application bake (PAB) process at a temperature of 100° C. for about 60 seconds. After the baking process, A Kratos Axis Supra X-ray Photoelectron Spectrometer collected XPS spectra of both coatings which were analyzed to produce an elemental analysis of the coating. The spectrometer employed a monochromated AlKα=1486.69 eV, 120 W (75 W survey)) X-ray source, hybrid (magnetic/electrostatic) optics (slot aperture, approx. 700 μm×300 μm analysis area), hemispherical analyzer, multichannel plate, and delay line detector (DLD). The analyzer was operated in fixed analyzer transmission (FAT) mode with survey scans taken with a pass energy of 160 eV and high-resolution scans with a pass energy of 20 eV. All data was acquired at normal emission.

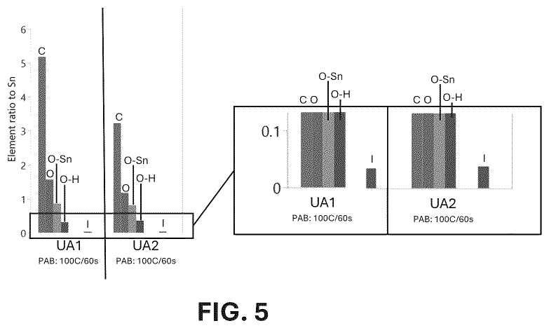

The quantity of each element as a ratio relative to the total amount of Sn detected in the film, as determined through analysis of the XPS spectra, is presented in FIG. 5. The XPS analysis was used to determine the relative abundance of C, O, and I relative to Sn. The chemical environment of oxygen atoms are further resolved to distinguish O—Sn moieties and OH moieties, with these values representing subsets of the total oxygen content, which is collectively labeled as ‘O’. Notably, the elemental analysis of wafers coated with the ammonium iodide enhanced precursor solutions (UA1 and UA2) after baking demonstrates the presence of iodine atoms in the film. The coating deposited from precursor solution UA1 (the solution having a 0.1:1 I:Sn ratio) was determined to have a I:Sn ratio of 0.035:1. The coating deposited from precursor solution UA2 (the solution having a 0.1:1 I:Sn ratio) was determined to have a I:Sn ratio of 0.038:1. Thus, a little more than a third of the iodine relative to tin was maintained following the processing. The coatings deposited from solutions UA1 and UA2 correspond to 35% and 38% iodine retention from precursor composition to processed film, respectively. This indicates that ammonium iodide enhanced organotin precursor solutions can be deposited to form organotin oxo-hydroxo coatings with incorporated iodine atoms. The molar ratio of Sn:Iodine can decrease from the precursor solution to the processed coating and the processed coating can comprise an appreciable amount of iodine atoms. No nitrogen was detected in the elemental analysis.

Example 7: Positive Tone Patterning with Ammonium Iodide Enhanced Organotin Photoresist Compositions.

An organotin photoresist precursor stock solution was prepared by combining a mixture of two organotin trialkoxides and a mixture of 38% 1-propanol/62% 1-penatol by weight to form a solution have a final Sn concentration of 0.06 M. Prior to formulation, the solvent mixture was normalized to comprise 300 ppm H₂O by mass. The stock solution was divided into three aliquots to form three photoresist precursor solution samples, according to Table 7. Precursor solution samples RA1 and RA2 comprised ammonium iodide (NH₄I) at a specified concentration and precursor solution sample RC is a comparative example which did not comprise ammonium iodide.

TABLE 7

| | | Organotin | | | |
|---|---|---|---|---|---|
| | Solvent | Composition | | | |
| Precursor | (Solvent, | (Compound, | [Sn] | NH₄I:Sn | [H₂O] |
| Solution | Weight %) | Molar %) | (M) | (Molar) | (ppm) |
| RC | 1-propanol, 38% | P1, 80% | 0.06 | 0 | 300 |
| | 1-pentanol, 62% | P2, 20% | | | |
| RA1 | 1-propanol, 38% | P1, 80% | 0.06 | 0.015 | 300 |
| | 1-pentanol, 62% | P2, 20% | | | |
| RA2 | 1-propanol, 38% | P1, 80% | 0.06 | 0.025 | 300 |
| | 1-pentanol, 62% | P2, 20% | | | |

The precursor solution were coated onto 300 mm Si wafers having an about 10 nm spin-on-glass underlayer via spin coating at a speed of about 1600 rpm to form coatings having a thickness of about 30 nm, as confirmed with ellipsometry. The coated wafers were then subjected to a post application bake process at a temperature of about 100° C. for about 60 seconds. In a subsequent exposure step, 13.5 nm EUV radiation was used to expose patterns of 22p38 contact holes onto the wafers using an ASML NXE:3400 scanner tool. The 22p38 patterns consisted of hexagonally arranged circular contact holes having a nominal diameter of 22 nm on a center to center pitch of 38 nm. In a procedure commonly referred to in the art as a dose meander exposure, each wafer comprised a plurality of exposure regions (pads) wherein identical 22p38 contact hole patterns were exposed onto each pad at a distinct dose from about 44 mJ/cm² to about 132 mJ/cm². The exposed wafers were then subjected to a post exposure bake (PEB) process for 60 seconds at a temperature of about 120° C., 140° C., or 160° C. Following baking, the wafers were developed in a positive tone development step using a developer solution of 2.38% wt. TMAH (aq.) to form positive tone patterns. The patterned wafers were then subjected to a thermal treatment (hardbake) at a temperature of about 100° C. for about 60 seconds.

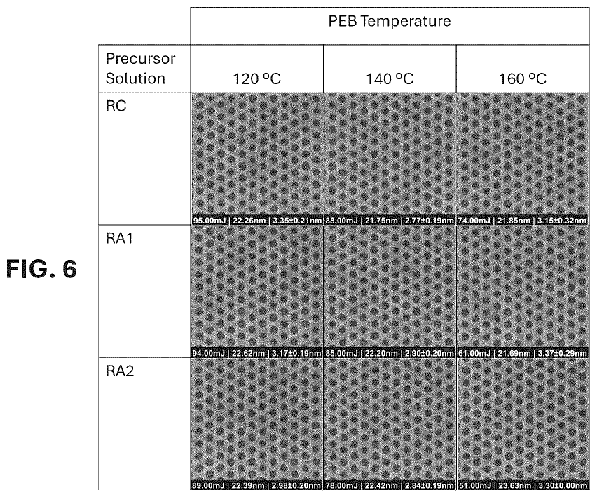

Scanning electron microscopy (SEM) images in combination with metrology software were used to analyze the positive tone patterns determine the dose that produced contact hole patterns with an average diameter closest to 22 nm (dose-to-size). The SEM images for each wafer at the dose to size are presented in FIG. 6 in addition to the measured characteristics: Dose (mJ/cm²) |Average Diameter (nm)|3σ LCDU (nm) under each image.

At all tested PEB temperatures (120° C., 140° C., and 160° C.), coatings deposited from ammonium iodide enhanced precursor solution RA1 required a lower EUV dose to achieve an average feature diameter of about 22 nm compared to those deposited from the non-enhanced control precursor solution RC. Furthermore, the EUV dose necessary to achieve an average diameter of about 22 nm was lower for coatings deposited from precursor solution RA2 (having 0.025:Sn NH₄I) than those deposited from precursor solution RA1 (having 0.015:Sn NH₄I). This indicates that the dose reduction realized by the addition of an ammonium iodide additive is proportional such that higher concentrations of additives can produce greater dose reduction effects. These results demonstrate that the addition of an ammonium-based iodide additive can enhance the sensitivity of organotin photoresist compositions and reduce the EUV dose necessary to achieve positive tone patterns of a desired critical dimension.

Notably, at a PEB temperature of 120° C., coatings deposited from both iodide enhanced precursor solutions RA1 and RA2 were determined to have a lower 30 LCDU than the control solution RC, with improvements of 0.18 nm and 0.37 nm, respectively. This indicates that the addition of an ammonium iodide additive to the precursor solution can reduce patterning dose while simultaneously improving pattern fidelity under certain thermal conditions. At PEB temperatures of 140° C. and 160° C., the 36 LCDU of the patterned coatings deposited from precursor solutions RA1 and RA2 was slightly higher than that of the control solution RC, although the increases were relatively low and did not exceed 0.17 nm and the drop in dose was greater. The relatively low compromises to pattern fidelity are particularly interesting, as decreased doses are generally accompanied by reductions in pattern quality as a result of photon shot noise. This indicates that at the tested PEB conditions, the addition of an ammonium iodide additive to the precursor solution decreases the dose without significantly compromising pattern quality.

Example 8: Negative Tone Contrast Behavior with Ammonium Iodide Enhanced Organotin Photoresist Compositions Comprising Secondary and Tertiary/Primary Organo Ligands.

This example suggests that for negative tone processing, the addition of ammonium iodide salts to organotin precursor solutions can increase the radiation sensitivity of films formed from solutions comprising primary and tertiary organo ligands and decrease the radiation sensitivity of films formed from solutions comprising secondary organo ligands.

Five samples of organotin precursor solutions were prepared by combining an organotin composition, an organic solvent blend, and optionally ammonium iodide, according to Table 8. The comparable organotin composition of samples ZC, ZA1, and ZA2 comprise a blend of tertiary and primary organo ligands. While the exact organotin compositions of samples ZC, ZA1, and ZA2 may differ, the patterning properties of organotin photoresists are known to be primarily influenced by the organo ligand identity which is identical for the three samples (20% CH3/80% tBu). The identical organotin compositions of samples YC and YA1 comprise secondary (isopropyl) organo ligands. Samples ZA1, ZA2, and YA1 were enhanced with an ammonium iodide additive, whereas samples ZC and YC are comparative examples and contained no additive.

TABLE 8

| | | Organotin | | | |
|---|---|---|---|---|---|
| | Solvent | Composition | | | |
| Precursor | (Solvent, | (Compound, | [Sn] | NH₄I:Sn | [H₂O] |
| Solution | Weight %) | Molar %) | (M) | (Molar) | (ppm) |
| ZC | 4-methyl | CH₃Sn(OtAm)₃, 20% | 0.05 | 0 | 300 |
| | 2-pentanol, | | | | |
| | 100% | tBuSn(OtAm)₃, 80% | | | |
| ZA1 | 1-propanol, 38% | CH₃Sn(OtAm)₃, 20% | 0.062 | 0.05 | 300 |
| | 1-pentanol, 62% | tBuSn(O-3Pent)₃, 80% | | | |
| ZA2 | 1-propanol, 38% | CH₃Sn(OtAm)₃, 20% | 0.062 | 0.1 | 300 |
| | 1-pentanol, 62% | tBuSn(O-3Pent)₃, 80% | | | |
| YC | 1-propanol, 38% | iPrSn(OsBu)₃, 100% | 0.062 | 0 | 300 |
| | 1-pentanol, 62% | | | | |
| YA1 | 1-propanol, 38% | iPrSn(OsBu)₃, 100% | 0.062 | 0.1 | 300 |
| | 1-pentanol, 62% | | | | |

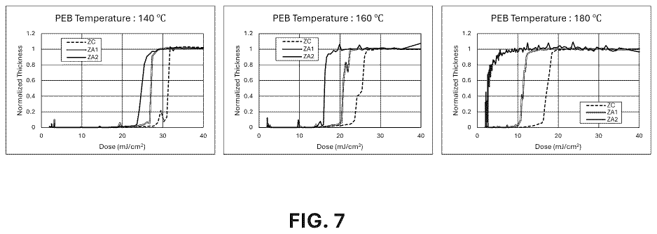

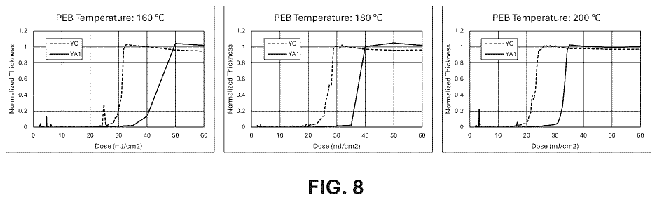

The five organotin precursor solutions were deposited onto 300 mm Si wafers with a spin-on glass underlayer via spin coating to form a coating having a thickness of about 26 nm, as confirmed by ellipsometry. The wafers were then subjected to a post application bake (PAB) for 60 seconds at 100° C. Fields of the wafers were exposed to varying doses of 13.5 nm EUV radiation from about 0 mJ/cm² to about 100 mJ/cm². The wafers were then subjected to a 60 second PEB at a temperature of either 140° C., 160° C., 180° C., or 200° C. The varying PEB temperatures were selected to align with the different thermal decomposition temperatures of the secondary vs. primary/tertiary ligand blends. The wafers were then developed in a negative tone development process using a solution of 5% wt acetic acid in PGMEA. The wafers were then subjected to a 60 second hard bake (HB) at a temperature of 250° C. Each field having received a varying radiation dose was measured using ellipsometry to determine the thickness of the material remaining post hard bake. The thickness values were normalized relative to the initial thickness such that a value of 1.0 indicates no material was removed during development and a value of 0 indicates that all the material was removed during development. The measured thickness values of each field and corresponding doses for all wafers were plotted to generate the contrast curves in FIGS. 7 and 8. FIG. 7 is a set of contrast curves for coatings deposited from precursor solutions with a primary/tertiary organo ligand blend: ZC, ZA1, and ZA2. FIG. 8 is a set of contrast curves for coatings deposited from precursor solutions with secondary organo ligands: YC and YA1.

As illustrated in FIG. 7, at all PEB temperatures, coatings formed from additive-enhanced precursor solutions ZA1 and ZA2 required a lower radiation dose to be rendered insoluble in the negative tone developer solution than coatings formed from non-additive-enhanced precursor solution ZC. This indicates that the addition of ammonium iodide can increase the radiation sensitivity of coatings formed from organotin precursor solutions comprising a blend of primary and tertiary organo ligands. Conversely, as illustrated in FIG. 8, coatings formed from additive-enhanced precursor solution YA1 required a higher radiation dose to be rendered insoluble in the negative tone developer solution than coatings formed from non-additive-enhanced precursor solution YC. It is not clear why the YA1 results exhibited decreased radiation sensitivity, which differed from the remaining results in the Examples, although the organo ligand being a secondary carbon is one identifiable difference. This indicates that the addition of ammonium iodide can decrease the radiation sensitivity of coatings formed from organotin precursor solutions comprising secondary organo ligands. This trend may or may not follow for additional concentrations of ammonium iodide and precursor solution compositions.

### Further Inventive Concepts:

X1. A radiation patternable organometallic coating comprising a tin oxo-hydroxo network with organo ligands bonded to the tin via Sn—C bonds and incorporated iodine, wherein the organo ligands comprise an alkyl, an aryl, an alkenyl, an alkynyl, or a cycloalkyl group with 1-31 carbon atoms wherein one or more carbon atoms are optionally substituted with heteroatoms.
X2. The coating of inventive concept X1 wherein the coating can be represented by the formula RSnO_{3/2-x/2-z/2}(OH)ₓI_{z} wherein 0<x+z<3, and 0.01<z<0.5.
X3. The coating of inventive concept X1 wherein the coating comprises iodine at a molar ratio from about 0.001 to about 0.5 relative to tin.
X4. The coating of inventive concept X1 wherein the organo ligands comprise methyl, ethyl, propyl, isopropyl, n-butyl, sec-butyl, isobutyl, or tert-butyl, or combinations thereof.
X5. The coating of inventive concept X1 comprising a blend of two or more different organo ligands.
X6. The coating of inventive concept X1 wherein the coating can be represented by (R, R′)SnO_{3/2-x/2-z/2}(OH)ₓI_{z} wherein 0<x+z<3, and 0.01<z<0.5, wherein R and R′ independently comprise an alkyl, an aryl, an alkenyl, an alkynyl, or a cycloalkyl group with 1-31 carbon atoms wherein one or more carbon atoms are optionally substituted with heteroatoms.

X7. The coating of inventive concept X6 wherein (R,R′)=RₐR_{b}, a+b=1 and a,b>0.05=5 mol %.

X8. The coating of inventive concept X5 wherein one organo ligand comprises an acetal group.
X9. The coating of inventive concept X1 wherein the coating has a thickness from about 1 nm to about 100 nm.
X10. The coating of inventive concept X1 wherein the coating has a thickness from about 2 nm to about 50 nm.
X11. The coating of inventive concept X1 comprising a concentration of the incorporated iodine from about 5 mole percent to about 75 mole percent relative to the tin.
X12. An article comprising a substrate and the radiation patternable coating of inventive concept X1.
X13. The article of inventive concept X12 wherein the substrate comprises Si.
X14. The article of inventive concept X12 wherein the radiation patternable coating comprises a physical pattern.
X15. The article of inventive concept X14 wherein the physical pattern comprises a regular pattern of holes.
X16. The article of inventive concept X15 wherein the holes have an average diameter less than 25 nm and a 36 LCDU of no more than about 3.5 nm.
X17. The coating of inventive concept X1 wherein the coating is deposited from a precursor solution comprising an organotin composition represented by the formula RSnL₃ and an ammonium-based iodide, wherein R comprises an alkyl, an aryl, an alkenyl, an alkynyl, or a cycloalkyl group with 1-31 carbon atoms wherein one or more carbon atoms are optionally substituted with heteroatoms, L is a hydrolysable ligand, and wherein the solution has a tin concentration from about 0.00025 M to about 1.0 M and the ammonium iodide is present at a molar ratio from about 0.001 to about 0.5 relative to the total concentration of tin.
X18. The coating of inventive concept X17 wherein the coating comprises iodine at a molar ratio relative to tin of at least 5% of the molar ratio of ammonium iodide relative to tin in the precursor solution.
X19. The coating of inventive concept X17 wherein the coating comprises iodine at a molar ratio relative to tin of at least 30% of the molar ratio of ammonium iodide relative to tin in the precursor solution.
X20. The coating of inventive concept X1 wherein the coating comprises iodine at a molar ratio relative to tin of at least 0.05%.
X21. The coating of inventive concept X1 wherein the coating comprises iodine at a molar ratio relative to tin of at least 0.25%.
Z1. A method for patterning an organometallic coating comprising a tin oxo-hydroxo network with organo ligands bonded to the tin via Sn—C bonds and incorporated iodine atoms, wherein the organo ligands comprise an alkyl, an aryl, an alkenyl, or a cycloalkyl group with 1-31 carbon atoms wherein one or more carbon atoms are optionally substituted with heteroatoms, the method comprising:
exposing a pattern of radiation of the coating to form a latent image comprising exposed and unexposed regions and
developing the coating with a developer composition to selectively remove either the exposed material or the unexposed material.
   Z2. The method of inventive concept Z1 wherein the radiation source is EUV radiation.
   Z3. The method of inventive concept Z2 wherein the pattern of radiation is exposed at a dose from about 1 mJ/cm² to about 150 mJ/cm².
   Z4. The method of inventive concept Z1 further comprising baking the coating at a temperature from about 45° C. to about 225° C. before developing the coating and after exposing a pattern of radiation.
   Z5. The method of inventive concept Z4 wherein the baking is performed for at least about 0.1 minutes to about 30 minutes.
   Z6. The method of inventive concept Z1 wherein the developing comprises a negative tone development process.
   Z7. The method of inventive concept Z6 wherein the developer composition comprises an organic solvent.
   Z8. The method of inventive concept Z6 wherein the developing comprises a solventless development process.
   Z9. The method of inventive concept Z8 wherein the developer composition comprises a plasma or a reactive developer gas.
   Z10. The method of inventive concept Z1 wherein the developing comprises a positive tone development process.
   Z11. The method of inventive concept Z10 wherein the developer composition comprises an aqueous base.
   Z12. The method of inventive concept Z11 wherein the aqueous base comprises tetramethyl ammonium hydroxide.
   Z13. The method of inventive concept Z1 wherein the organic ligands comprise a blend of different ligands.
   Z14. The method of inventive concept Z13 wherein the organic ligands comprise acetal ligands.
   Z15. The method of inventive concept Z14 wherein the organic ligands further comprise cycloalkyl ligands.
   Z16. The method of inventive concept Z1 wherein the organometallic coating comprises a radical scavenger additive at a concentration from about 0.000025 M to about 0.4 M.
   Z17. The method of inventive concept 16 wherein the radical scavenger additive comprises a hindered amine, a hindered phenol, TEMPO, BHT, BHA, TEMPOL, PTIO, or a combination thereof.
   Z18. The method of inventive concept 1 further comprising an aromatic onium ion or a neutral analog thereof.
   Z19. The method of inventive concept Z18 wherein the aromatic onium ion comprises triphenylsulfonium⁺ at a concentration from about 0.000025 M to about 0.4 M.
   A1. A composition comprising:
an organotin iodo-alkoxide compound represented by the formula RSn(OR′)₃₋ₓIₓ, and
an organotin alkoxide compound represented by the formula RSn(OR′)₃, wherein R is an organo ligand with one or more carbon atoms,
wherein the organo ligand comprises an alkyl, an aryl, an alkenyl, or a cycloalkyl group with 1-31 carbon atoms optionally substituted with one or more heteroatoms, R′ is an organo group with 1 to 10 carbon atoms, and x is 1, 2, 3 or a mixture thereof and has a carbon-tin bond.
   A2. The composition of inventive concept A1, wherein R comprises methyl, ethyl, n-propyl, isopropyl, n-butyl, tert-butyl, or isobutyl.
   A3. The composition of inventive concept A1, wherein R′ is comprises methyl, ethyl, n-propyl, isopropyl, n-butyl, tert-butyl, or tert-amyl.
   A4. The composition of inventive concept A1, wherein the organotin iodo-alkoxide compound is present at a molar amount from about 1% to about 50% relative to the total molar tin amount.
   A5. The composition of inventive concept A4, wherein the organotin iodo-alkoxide compound is present at a molar amount from about 1% to about 10% relative to the total molar tin amount.
   A6. The composition of inventive concept A1 wherein the overall organotin composition is represented by the formula RSn(OR′)_{3-y}I_{y} wherein 0.01>y>2 and y is obtained from the relative amounts of iodo-alkoxide and the value of x.
   A7. The composition of inventive concept A1 further comprising an organotin iodo-alkoxide compound represented by the formula R″Sn(OR′″)₃, wherein R″ is an organo ligand with one or more carbon atoms and comprises an alkyl, an aryl, an alkenyl, or a cycloalkyl group with 1-31 carbon atoms optionally substituted with one or more heteroatoms, R′″ is an organo group with 1 to 10 carbon atoms, which may be the same or different from R′, and R″ has a carbon tin bond.
   A8. The composition of inventive concept A1, further comprising an organic solvent.
   A9. The composition of inventive concept A8, wherein the organic solvent comprises an alcohol or a mixture of alcohols.
   B1. A method of forming a radiation patternable coating, comprising:
depositing a composition comprising a solvent and an organotin iodo-alkoxide composition represented by the formula RSn(OR′)₃₋ₓIₓ onto a substrate, wherein R is an organo ligand with one or more carbon atoms and wherein the organo ligand comprises an alkyl, an aryl, an alkenyl, or a cycloalkyl group with 1-31 carbon atoms optionally substituted with one or more heteroatoms, R′ is an organo group with 1 to 10 carbon atoms, and x is 1, 2, or 3; and
forming a radiation patternable organotin oxo-hydroxo-iodo coating on the substrate.
   B2. The method of inventive concept B1, wherein R comprises methyl, ethyl, n-propyl, isopropyl, n-butyl, tert-butyl, or isobutyl.
   B3. The method of inventive concept B1, wherein R′ comprises methyl, ethyl, n-propyl, isopropyl, n-butyl, tert-butyl, or tert-amyl.
   B4. The method of inventive concept B1, wherein the organotin iodo-alkoxide composition comprises a blend of organotin alkoxide compounds represented by the formulas RSn(OR′)₃, RSn(OR′)₂I, RSn(OR′)I₂, and RSnI₃.
   B5. The method of inventive concept B1, wherein the organotin iodo-alkoxide composition is present at a molar concentration of from about 1% to about 50% relative to the total tin concentration.
   B6. The method of inventive concept B1, further comprising heating the radiation patternable organotin oxo-hydroxo-iodo coating at a temperature from about 45° C. to about 225° C.
   B7. The method of inventive concept B1 wherein depositing comprises spin coating of a precursor solution having a solvent and wherein forming comprises providing for solvent evaporation.
   B8. The method of inventive concept B1 wherein depositing comprises vapor depositing and wherein forming comprises annealing by heating the radiation patternable organotin coating with the oxo-hydroxo-iodo network at a temperature from about 45° C. to about 225° C.
   C1. A radiation patternable coating comprising:
an organotin oxo-hydroxo-iodo network comprising a material represented by the stoichiometry RSnO_{3/2-x/2-z/2}(OH)ₓI_{z}, wherein R is an organo ligand with one or more carbon atoms and wherein the organo ligand comprises an alkyl, an aryl, an alkenyl, or a cycloalkyl group with 1-31 carbon atoms optionally substituted with one or more heteroatoms, 0<x+z<3, and 0.01<z<0.5.
   C2. The radiation patternable coating of inventive concept C1, wherein R comprises methyl, ethyl, n-propyl, isopropyl, n-butyl, tert-butyl, or isobutyl.
   C3. The radiation patternable coating of inventive concept C1, wherein 0.05<z<0.4.
   C4. The radiation patternable coating of inventive concept C1, wherein the coating has a thickness from 1 nm to 100 nm.
   C5. The radiation patternable coating of inventive concept C3, wherein the thickness is from 1 nm to 50 nm.
   C6. The radiation patternable coating of inventive concept C1, wherein the coating is patternable by extreme ultraviolet (EUV) radiation.
   C7. The radiation patternable coating of inventive concept C1, wherein the organotin oxo-hydroxo-iodo network further comprises moieties represented by the formula R′Sn, wherein R′ is distinct from R and is an organo ligand with one or more carbon atoms optionally substituted with one or more heteroatoms and wherein the organo ligand comprises an alkyl, an aryl, an alkenyl, or a cycloalkyl group with 1-31 carbon atoms optionally substituted with hetero atoms.
   D1. A method for synthesizing an organo tin iodide composition, the method comprising reacting RSn(OR′)₃ with SnI₂ in an inert solvent to form a mixture of reaction products comprising RSn(OR′)₃₋ₓIₓ, 0<x<3, and a Sn(II) byproduct, wherein RSn(OR′)₃₋ₓI, represents a mixture of RSn(OR′)₃, RSn(OR′)₂I, RSn(OR′)I₂, RSnI₃, in relative amounts to give x as the average number of I ligands, wherein R is an organo ligand comprises an alkyl, an aryl, an alkenyl, or a cycloalkyl group with 1-31 carbon atoms optionally substituted with one or more heteroatoms and/or unsaturated/aromatic groups and with a carbon atom bound to the tin, and R′ is an organo group with 1 to 10 carbon atoms.
   D2. The method of inventive concept D1 wherein the inert solvent is an aromatic solvent.
   D3. The method of inventive concept D1 where the inert solvent is toluene.
   D4. The method of inventive concept D1 wherein the Sn(II) byproduct is insoluble in the inert solvent.
   D5. The method of inventive concept D4 further comprising filtering the mixture of reaction products to obtain a high purity reaction product.
   D6. The method of inventive concept D1 wherein the RSn(OR′)₃ and SnI₂ are reacted for at least 12 hours.
   D7. The method of inventive concept D1 wherein the RSn(OR′)₃ and SnI₂ are reacted for at least 72 hours.
   D8. The method of inventive concept D1 wherein R is tert-butyl.
   D9. The method of inventive concept D1 wherein the ratio of reaction products RSn(OR′)₃: RSn(OR′)₂I:RSn(OR′)I₂ is approximately 1:2:1.
   D10. The method of inventive concept D1 wherein the mixture of reaction products is represented by the overall formula RSn(OR′)₂I.
   D11. The method of inventive concept D1 wherein R′ is tert amyl oxide (OtAm).

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to expected uncertainties in the associated values as would be understood in the particular context by a person of ordinary skill in the art. A person of ordinary skill in the art is notified that the assertions above regarding the contemplation of subranges within explicit ranges are sincerely intended to provide explicit written description for the subranges, as clearly suggested, even though not explicitly written and that the subranges are not believed to change the character of the associated invention, although of course the specific values of parameters will certainly quantitatively change corresponding results obtained, which could influence patentability even though the basic character of the invention may not be changing, in view of the potential nature of the state of the art known or unknown at filing given that the inventiveness may follow from the factual details. A person of ordinary skill in the art is further notified that upper and lower values of explicit ranges and values within explicit ranges are intended to provide explicit written description for endpoints of subranges, furthermore explicit disclosure of upper and/and lower values of explicit ranges of a certain feature are intended to be disclosed as upper and/or lower values for additional ranges, including subranges.

What is claimed is:

1. A photoresist precursor solution comprising a mixture of:
a solvent,
an organotin composition represented by the formula RSnL₃ and
an ammonium-based iodide compound represented by the formula NR″₄I,
wherein R is a organo ligand with one or more carbon atoms optionally substituted with one or more heteroatoms and wherein the organo ligand comprises an alkyl, an aryl, an alkenyl, or a cycloalkyl group with 1-31 carbon atoms with a carbon atom bound to the tin, L is a hydrolysable ligand, and each R″ is independently hydrogen or an organo group with 1 to 10 carbon atoms.

2. The photoresist precursor solution of claim 1 wherein the solution has a tin concentration from about 0.0025 M to about 1.0 M.

3. The photoresist precursor solution of claim 1 wherein the hydrolysable ligand is amide (—NR¹R²), acetylide (—C≡CR¹), or carboxylate (COOR¹) wherein R¹ and R² are independently alkyl groups having from 1 to 10 carbon atoms and optionally substituted with one or more unsaturated carbon-carbon bonds and/or heteroatoms.

4. The photoresist precursor solution of claim 1 wherein the hydrolysable ligand is alkoxide (—OR¹), wherein R¹ is an alkyl group having from 1 to 10 carbon atoms and optionally substituted with one or more unsaturated carbon-carbon bonds and/or heteroatoms.

5. The photoresist precursor composition of claim 3 wherein R¹ and R² independently comprise methyl, ethyl, n-propyl, isopropyl, n-butyl, tert-butyl, or tert-amyl.

6. The photoresist precursor solution of claim 1 wherein R comprises methyl, ethyl, propyl, isopropyl, n-butyl, sec-butyl, isobutyl, or tert-butyl, or combinations thereof.

7. The photoresist precursor solution of claim 1 wherein R comprises an acetal group represented by the formula (OR⁴)(OR³)R²CR¹, wherein R¹ is a substituted or unsubstituted hydrocarbyl group having from 1 to 15 carbon atoms and forms a Sn—C bond, R² is hydrogen or a substituted or unsubstituted hydrocarbyl group having from 1 to 15 carbon atoms, wherein R³ and R⁴ are independently substituted or unsubstituted hydrocarbyl groups having 1 to 4 carbon atoms or wherein R³ and R⁴ collectively form a bridging structure —OR⁵O—(R⁵=R³+R⁴) where R⁵ is a hydrocarbyl group having 1 to 10 carbon atoms and forms a cyclic linkage between the acetal O atoms.

8. The photoresist precursor solution of claim 1 wherein all four of R″ comprise hydrogen.

9. The photoresist precursor solution of claim 1 wherein the ammonium-based iodide compound is a quaternary ammonium iodide.

10. The photoresist precursor solution of claim 1 wherein the ammonium-based iodide compound is ammonium (NH₄⁺) iodide, tetramethyl ammonium iodide, tetrabutyl ammonium iodide, anilinium iodide (C₆H₅NH₃I), or a combination thereof.

11. The photoresist precursor solution of claim 1 wherein the ammonium-based iodide compound comprises an ammonium ion with at least one hydrogen substituent.

12. The photoresist precursor solution of claim 1 wherein the ammonium-based iodide compound is present at a molar ratio of about 0.001 to about 0.5 relative to the total tin concentration.

13. The photoresist precursor solution of claim 1 wherein the solvent comprises an alcohol, an ester, an ether, an alkane, an aromatic hydrocarbon, or a combination thereof.

14. The photoresist precursor solution of claim 1 further comprising a second organotin composition represented by the formula R′SnL′ wherein R′ is an organo ligand with one or more carbon atoms optionally substituted with one or more heteroatoms and wherein the organo ligand comprises an alkyl, an aryl, an alkenyl, or a cycloalkyl group with 1-31 carbon atoms and is different from R, and wherein L′ is a hydrolysable ligand and is the same or different from L.

15. The photoresist precursor solution of claim 14 wherein the organotin composition comprises a blend of the compounds represented by Structure 1 and Structure 2, wherein the blend is from about 2% by mole of Structure 1 to about 98% by mole of Structure 1 and the remainder is Structure 2

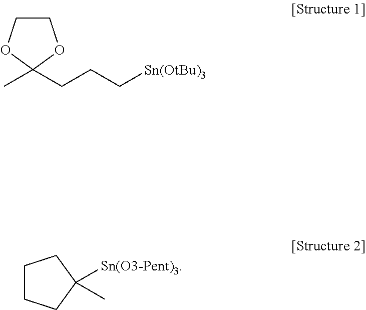

16. The photoresist precursor solution of claim 1 further comprising water adjusted to be at a concentration from about 200 ppm by mass to about 10,000 ppm by mass.

17. The photoresist precursor solution of claim 1 further comprising a radical scavenger additive at a concentration from about 0.000025 M to about 0.4 M.

18. The photoresist precursor composition of claim 17 wherein the radical scavenger additive comprises a hindered amine, a hindered phenol, TEMPO, BHT, BHA, TEMPOL, PTIO, or a combination thereof.

19. The photoresist precursor composition of claim 1 further comprising an aromatic onium ion or zwitterion at a concentration from about 0.000025 M to about 0.4M.

20. The photoresist precursor composition of claim 19 wherein the aromatic onium ion comprises triphenylsulfonium.

21. The photoresist precursor composition of claim 19 wherein the aromatic onium ion has one or more counterions comprising iodide.

22. A method for preparing a photoresist precursor solution comprising combining in any order:
a solvent,
an organotin composition represented by the formula RSnL₃ and
an ammonium-based iodide compound represented by the formula NR″₄I,
wherein R is an organo ligand with one or more carbon atoms optionally substituted with one or more heteroatoms and wherein the organo ligand comprises an alkyl, an aryl, an alkenyl, or a cycloalkyl group with 1-31 carbon atoms, L is a hydrolysable ligand, and each R″ is independently hydrogen or an organo group with 1 to 10 carbon atoms.

23. A photoresist precursor solution prepared using the method of claim 22.
